(19) United States
(12) Patent Application Publication
(10) Pub. No.: US 2025/0328709 A1
(43) Pub. Date: Oct. 23, 2025

(54) LONG DURATION ENERGY STORAGE

(71) Applicant: Quanta Technology, LLC, Raleigh, NC (US)

(72) Inventors: Ralph David Masiello, Carson City, NV (US); Farnaz Farzan, Livingston, NJ (US); Khashayar Mahani, Brooklyn, NY (US); Farbod Farzan, Weehawken, NJ (US)

(21) Appl. No.: 19/184,477

(22) Filed: Apr. 21, 2025

Related U.S. Application Data
(60) Provisional application No. 63/637,094, filed on Apr. 22, 2024.
(60) Provisional application No. 63/785,385, filed on Apr. 8, 2025.

(51) Int. Cl. G06F 30/27

(52) U.S. Cl. CPC G06F 30/27

(57) ABSTRACT

An electric power system (10) is supplied at least in part by renewable energy sources (12). A method for managing storage of energy in such a system includes obtaining a stochastic model (16) that models probabilistic variability (22) in weather (20) across a sequence of time periods (P-1 . . . P-N) within a time horizon (18), each time period (P-n) being at least one day in duration. The method further includes determining, using the stochastic model (16), one or more values (24V) for one or more design or operational parameters (24) of the electric power system (10) that optimize a level of energy (L-1 . . . . L-N) stored by the electric power system (10) at each time period (P-1 . . . P-N) by minimizing an expected impact of renewable energy production variation occurring over the time horizon (18) due to the modeled probabilistic variability (22) in weather (20).

### RELATED APPLICATIONS

The present application claims priority to U.S. Provisional Patent Application No. 63/637,094 filed Apr. 22, 2024 entitled “LONG DURATION ENERGY STORAGE”, and claims priority to U.S. Provisional Patent Application No. 63/785,385 filed Apr. 8, 2025 entitled “LONG DURATION ENERGY STORAGE”, both applications being incorporated herein by reference in their entirety.

### TECHNICAL FIELD

The present application relates generally to an electric power system and relates more particularly to management of energy storage in an electric power system.

### BACKGROUND

Typical intra-hour variability in energy supply and demand can generally be managed effectively using existing short-duration (<4 hours) energy storage technologies. Such short-term storage solutions such as batteries or flywheels cater to rapid discharge and charge cycles within shorter timeframes. By contrast, long duration energy storage (LDES) systems are engineered to address the need for balancing energy supply and demand over more prolonged durations. For example, pumped hydroelectric storage pumps water uphill during surplus electricity periods and releases the water downhill through turbines to generate power when demand peaks. Compressed Air Energy Storage (CAES) compresses air using excess electricity and stores it underground for later use in power generation. Thermal energy storage methods involve capturing and storing heat or cold for later conversion into electricity or direct use. Flow batteries and hydrogen storage are also emerging as viable options for long duration energy storage, helping to support the integration of renewable energy sources into the grid by managing intermittent generation and improving overall grid stability and resilience. These technologies will play a critical role in advancing the transition towards cleaner and more sustainable energy systems.

Systems designed for storage durations between 4 and 24 hours may sometimes be categorized as long duration energy storage (LDES) but they do not encompass true multi-day storage scenarios. One primary application of this intermediate LDES is peak shaving or storing surplus energy during the day for release at night when solar photo-voltaic (PV) generation is minimal or zero.

The true challenge arises with multi-day storage, which constitutes the essence of LDES and is particularly relevant in environments aiming for very high levels or 100% reliance on renewable energy sources. The challenge here encompasses how to best design the power system (e.g., in terms of LDES storage capacity versus additional renewable energy sources and/or load curtailment) and/or how to operate the power system day-to-day (e.g., how much stored energy should be kept in reserve at the end of the day), in a way that accounts for the multi-day nature of LDES.

Traditional approaches to designing and operating a power system only account for energy storage durations less than 12 hours, due to the reliance on Security Constrained Unit Commitment and hour by hour optimization as the underpinning platform. Because energy storage supplements energy generation, these traditional approaches treat energy storage as another source of energy generation so as to effectively fit energy storage into traditional paradigms for power system design and operation. According to these approaches, then, the power system is designed and operated based on optimizing the schedule according to which energy storage is charged and discharged, e.g., whereby the decision-variable is how much to charge or discharge energy storage at any given time.

Extensions of these traditional approaches that aim to capture the multi-day nature of LDES still fundamentally treat energy storage as another source of energy generation. These approaches account for how weather will affect energy storage as a source of energy generation over multiple days, but do so in a deterministic way, i.e., given the weather, what is the optimal schedule according to which to charge or discharge energy storage.

A need remains for an improved approach to designing and/or operating a power system in a way that better accounts for the multi-day nature of LDES, especially one that more realistically regards weather as being uncertain rather than deterministic.

### SUMMARY

Some embodiments herein enable design and/or operation of a power system with multi-day energy storage, e.g., that is supplied at least in part by renewable energy sources. Some embodiments in this regard design and/or operate the power system based on optimizing the level of energy stored each day (or more) within a time horizon, e.g., so as to treat stored energy as inventory rather than a source of energy generation. Some embodiments alternatively or additionally design and/or operate the power system in a way that regards weather as uncertain rather than as deterministic, e.g., so as to account for corresponding uncertainty in renewable energy production attributable to uncertainty in the weather. For example, some embodiments design and/or operate the power system using a stochastic model that models probabilistic variability in weather over the time horizon.

More particularly, embodiments herein include a method for managing storage of energy in an electric power system supplied at least in part by renewable energy sources. The method comprises obtaining a stochastic model that models probabilistic variability in weather across a sequence of time periods within a time horizon, each time period being at least one day in duration. The method also comprises determining, using the stochastic model, one or more values for one or more design or operational parameters of the electric power system that optimize a level of energy stored by the electric power system at each time period by minimizing an expected impact of renewable energy production variation occurring over the time horizon due to the modeled probabilistic variability in weather.

Other embodiments herein include a non-transitory computer-readable storage medium on which is stored instructions. In some embodiments, when executed by processing circuitry of equipment, the non-transitory computer-readable storage medium causes the equipment to obtaining a stochastic model that models probabilistic variability in weather across a sequence of time periods within a time horizon, each time period being at least one day in duration. In some embodiments, when executed by processing circuitry of equipment, the non-transitory computer-readable storage medium causes the equipment to determining, using the stochastic model, one or more values for one or more design or operational parameters of an electric power system that optimize a level of energy stored by the electric power system at each time period by minimizing an expected impact of renewable energy production variation occurring over the time horizon due to the modeled probabilistic variability in weather.

Still other embodiments herein include corresponding apparatus, computer programs, and carriers of those computer programs.

### BRIEF DESCRIPTION OF THE DRAWINGS

FIG. 1 is a block diagram of a power system and equipment for managing storage of energy in the power system according to some embodiments that leverage a stochastic model.

FIG. 2 is a block diagram of a power system and equipment for managing storage of energy in the power system according to other embodiments that leverage a stochastic model.

FIG. 3 is a logic flow diagram of a method for determining long duration energy storage requirements according to some embodiments.

FIG. 4 is a block diagram of a Markov chain model of weather according to some embodiments.

FIG. 5 is a block diagram of a Markov chain model of weather according to other embodiments that limit the number of consecutive days for which the same type of weather is allowed to persists.

FIG. 6 is a block diagram of a Markov chain model of weather according to other embodiments that model weather differently for different months of the year.

FIG. 7 is a transition matrix for a Markov chain model of weather according to some embodiments.

FIG. 8 is a plot diagram of a Markov chain model of weather with transition probabilities according to some embodiments.

FIG. 9 is a line graph showing example simulations of state transitions over a month according to some embodiments.

FIG. 10 is a line graph showing example resource inadequacy according to simulations of state transitions over a month according to some embodiments.

FIG. 11 is a line graph showing example storage state of charge according to simulations of state transitions over a month according to some embodiments.

FIG. 12 is a line graph showing example load lost each day according to simulations of state transitions over a month according to some embodiments.

FIG. 13 is a graph showing expected load lost statistics as averages according to one example.

FIG. 14 is a graph showing expected load lost statistics as averages plus two sigma according to another example.

FIG. 15 is a graph showing max load lost according to another example.

FIG. 16 is a block diagram of an LDES assessment framework according to some embodiments.

FIG. 17 is a block diagram of an example Markov chain model of weather according to some embodiments.

FIG. 18 is a block diagram of an example Markov chain model according to other embodiments where the states are defined by a combination of weather and storage state of charge.

FIG. 19 is a block diagram of an example Markov chain model according to still other embodiments.

FIG. 20 is a block diagram of example transition trees in an example Markov chain model according to some embodiments.

FIG. 21 is a logic flow diagram of a method for managing storage of energy in a power system according to some embodiments.

FIG. 22 is a block diagram of equipment for managing storage of energy in a power system according to some embodiments.

### DETAILED DESCRIPTION

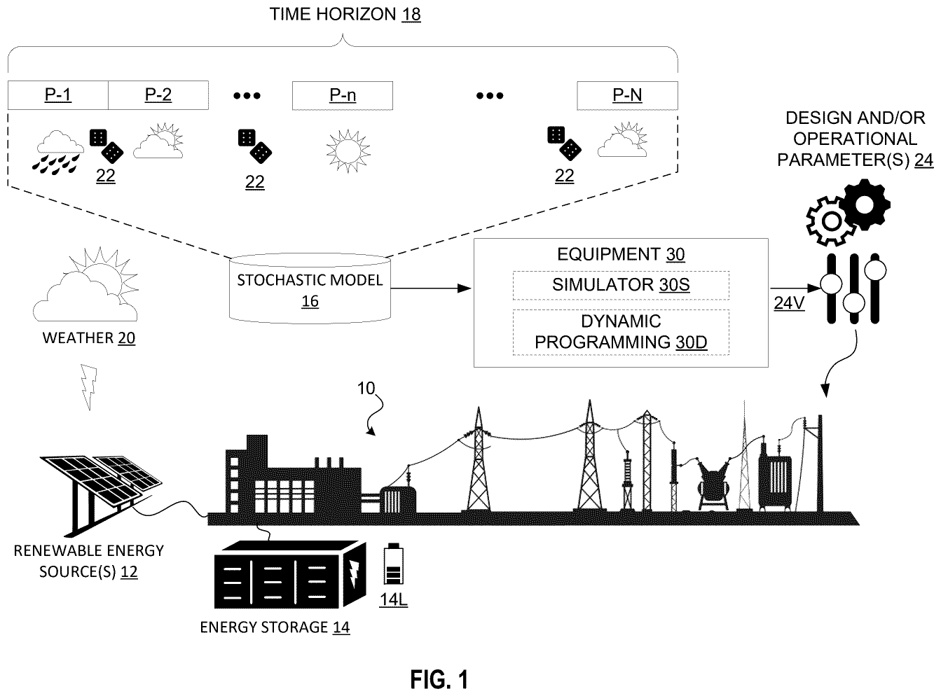

FIG. 1 shows a power system 10 according to some embodiments, e.g., in the form of an electric power system. The power system 10 as shown is supplied at least in part by renewable energy source(s) 12, e.g., solar, wind, and/or hydro energy sources. In these and other embodiments, then, the production of renewable energy in the power system 10 may be directly or indirectly impacted by the weather 20. For example, where the renewable energy source(s) 12 include photovoltaic (PV) sources, the production of energy by such sources may be higher on days with certain types of weather 20 (e.g., sunny skies) than on days with other types of weather 20 (e.g., cloudy or rainy).

Due at least in part to this weather-dependent variability in renewable energy production, the power system 10 further includes energy storage 14. Energy storage 14 is configured to store energy for a relatively long duration, e.g., at least one day in duration. The energy storage 14 may for instance be multi-day long duration energy storage (LDES). The energy storage 14 may be charged with excess energy produced on one day (e.g., a day with weather that yields high renewable energy production), and kept in reserve for discharging on another day (e.g., a day with weather that yields only low renewable energy production). For example, the power system 10 may capture excess energy generated during favorable weather conditions—such as sunny or windy periods—and retain it for subsequent use during adverse weather when renewable production diminishes.

Embodiments herein concern how to design and/or operate the power system 10 in this context with energy storage 14. Some embodiments for example concern how to best design (e.g., plan) the capacity of the power system's energy storage 14 and/or the capacity of the power system's renewable energy generation. Other embodiments concern how to best design sub-portfolios of energy storage 14 with different duration ratings. Still other embodiments alternatively or additionally concern how to best operate the power system 10 in terms of a schedule according to which energy storage 14 is charged and/or discharged. Generally, then, FIG. 1 shows that embodiments herein determine respective value(s) 24V of design and/or operational parameter(s) 24 of the power system 10, e.g., where the parameter(s) 24 may govern or dictate the design and/or operation of the power system 10 as described. FIG. 1 shows that the value(s) 24V of the design and/or operational parameter(s) 24 may be determined by equipment 30 associated with the power system 10.

Notably, equipment 30 according to some embodiments herein exploits a stochastic model 16 for determining the value(s) 24V of the design and/or operational parameter(s) 24. The stochastic model 16 may for instance take the form of a Markov chain model. Regardless of its form, though, the stochastic model 16 models probabilistic variability 22 in the weather 20 across a sequence of time periods P-1 . . . P-N (generally time periods P) within a time horizon 18. Each time period P may for instance be at least one day in duration, e.g., such that the time horizon 18 spans multiple days. The time horizon 18 may for example span multiple weeks, multiple months, or a year or more. Regardless, the stochastic model 16 may model probabilistic variability 22 in the weather 20 by, for each time period P and for each of multiple classifications of weather 20, model the probability that the weather 20 in that time period P will be of that classification. Different types of weather 20 may for instance be discretely classified based on an extent to which each type of weather 20 impacts renewable energy production, e.g., some types of weather such as sunny skies may be classified as being normal weather with no negative impact on renewable energy production, other types of weather such as partly cloud may be classified as being mild weather with moderate negative impact on renewable energy production, and still other types of weather such as rain may be classified as being severe weather with significant negative impact on renewable energy production. In these and other embodiments, then, the stochastic model 16 may consider different possible classifications of weather 20 as being possible in each time period P, but with potentially different probabilities of occurrence. Where the stochastic model 16 is a Markov chain model, for instance, the stochastic model 16 may have different states for each time period P corresponding to different classifications of weather 20 that are possible in that time period P, with the transition between states for different time periods P being associated with the probability of the weather 20 changing from one classification to another classification between those time periods P. In these and other embodiments, then, the stochastic model 16 may advantageously account for uncertainty in the weather 20, rather than selectively considering only certain weather scenarios deterministically.

Some embodiments nonetheless model the probabilistic variability 22 in weather 20 in a way that reflects the reality that weather 20 of a certain classification will never persist indefinitely. In some embodiments, then, the stochastic model 16 limits the number of successive time periods P for which the same weather 20 is able to persist, e.g., the same classification of weather cannot persist for more than 3 or 4 time periods in a row. Or, at the very least, the stochastic model 16 may model decreasing probability for the same weather 20 to persist over multiple successive time periods P, e.g., with sharply decreasing probability of the same classification of weather occurring after more than 3 or 4 time periods in a row.

According to other embodiments herein, the stochastic model 16 alternatively or additionally models different probabilistic variability 22 in weather 20 during different successive sets of time periods P, e.g., where different sets of time periods P may correspond to different seasons of weather or different months of the year. The stochastic model 16 in such a case may for instance be a multi-stage model that is formed from the combination of multiple set-specific stochastic models which are specific to respective sets of time periods P. For example, the stochastic model 16 may be formed from multiple season-specific stochastic models, e.g., one model for Spring, another model for Summer, another model for Fall, and yet another model for Winter. Or, for even finer granularity, the stochastic model 16 may be formed from multiple month-specific stochastic models, one for each month of the year. Regardless, in some embodiments, the end state probabilities of one set-specific stochastic model may be used as initial state starting probabilities of another set-specific stochastic model that is specific to a next set of time periods P in the time horizon 18, e.g., so as to form a cohesive, interconnected chain of set-specific stochastic models.

In any event, equipment 30 notably uses the stochastic model 16 to determine value(s) 24V for the design and/or operational parameter(s) 24. In particular, equipment 30 determines, using the stochastic model 16, value(s) 24V for the design and/or operational parameter(s) 24 to be those that optimize a level of energy 14L stored by the power system 10 at each time period P. By focusing on optimizing the stored energy level 14L at each time period P, as opposed to optimizing the charge/discharge schedule, some embodiments may treat the stored energy as inventory rather than as a source of energy generation.

Generally, though, the stored energy level 14L is optimized in some embodiments by minimizing the expected impact of renewable energy production variation occurring over the time horizon 18 due to the modeled probabilistic variability 22 in weather 20. This expected impact may be quantified in some embodiments in terms of an expected cost metric. The expected cost metric may for instance be a function of (e.g., a sum of) an expected cost of renewable energy production and/or an expected value of lost load due to renewable energy production variation. Either way, the stored energy level 14L in such case may be optimized by minimizing the expected cost metric, e.g., minimizing the total expected cost of renewable energy production variation occurring over the time horizon 18 due to the modeled probabilistic variability 22 in weather 20.

Alternatively or additionally, the expected impact of renewable energy production variation may account for the expected impact of renewable energy production shortfall occurring over the time horizon 18 due to the modeled probabilistic variability 22 in weather 20, e.g., in terms of a difference between an amount of renewable energy required to meet demand and an amount renewable energy available to meet demand. For example, some embodiments aim to optimize the stored energy so that it is at a level 14L that is sufficient to bridge any expected renewable shortfalls within the time horizon 22, at least with a target confidence level. Such embodiments may exploit the energy storage 14 to buffer the power system 10 against shortfalls in daily renewable energy production caused by variation in weather 20.

No matter the particular basis for optimizing the stored energy level 14L, the equipment 30 in some embodiments exploits a simulator 30S to do so. In such a case, the equipment 30 by way of the simulator 30S performs simulations that simulate changes in the level of energy 14L stored by the power system 10 across the time periods P as weather 20 probabilistically varies according to the stochastic model 16 and impacts renewable energy production. The simulations may for instance be Monte Carlo simulations. For each of the simulations, the equipment 30 calculates an impact of any renewable energy production variation that occurs over the time horizon 18 in the simulation. The simulations may thereby inform the equipment 30 about what minimizes the impact of renewable energy production variation due to weather variation.

In some embodiments, then, the simulator 30S may perform respective simulations for different candidate sets of value(s) 24V for the design and/or operational parameters 24. This way, the equipment 30 may compare the calculated impacts resulting from the simulations and determine which candidate set of value(s) 24V optimizes the stored energy level 14L at each time period P, e.g., as whatever candidate set has the minimum calculated impact of renewable energy production variation.

The equipment 30 in other embodiments by contrast exploits dynamic programming 30D, e.g., to calculate the optimal stored energy level 14L using a closed-form or near closed-form expression. For example, in embodiments where the stochastic model 16 is a Markov chain model, dynamic programming 30D may find which state transition path through states of the stochastic model 16 optimizes an objective function, e.g., wherein the objective function may be optimized by minimizing a cost metric that quantifies the expected impact of renewable energy production variation occurring over the time horizon 18. In one such embodiment, each state may be associated with an award cost that is a function of an expected cost of renewable energy production in that state and/or an expected value of load lost due in that state, and each transition between states may be associated with a transition cost. The cost metric for each state transition path in this case may be a function of a sum of award costs and transition costs associated with states in the state transition path, e.g., weighted by respective probabilities of transitions between the states in the state transition path.

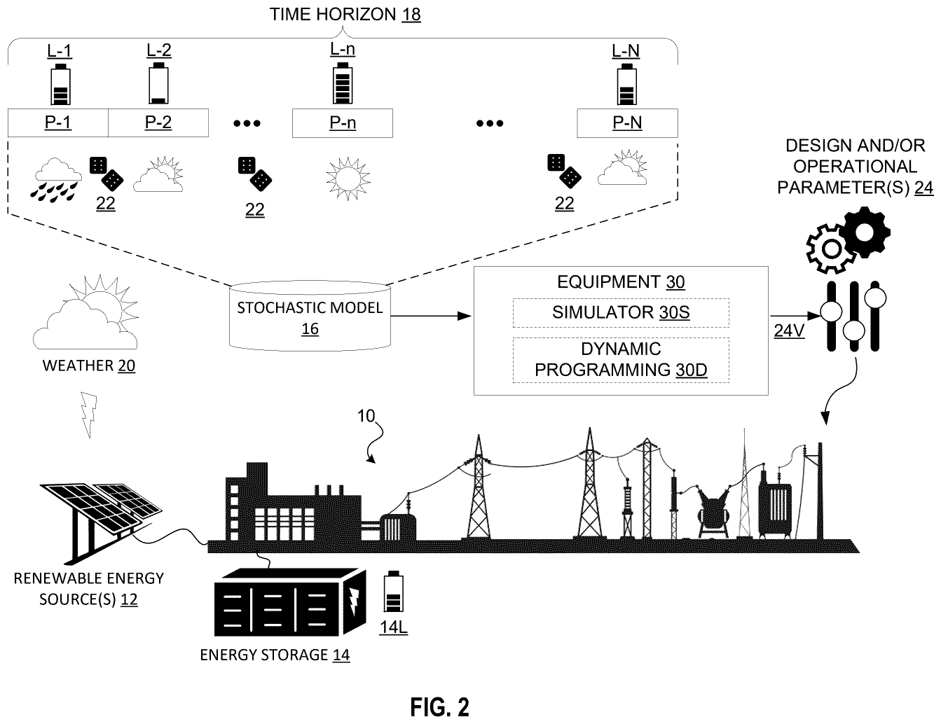

In some embodiments, such as those that exploit dynamic programming, the stochastic model 16 not only models probabilistic variability 22 in weather 20 but does so in combination with modeling associated probabilistic variability 22 in energy storage level across the time periods P in the sequence. FIG. 2 illustrates such a stochastic model 16 by showing each time period P in the stochastic model 16 as also being associated with a stored energy level L-1 . . . . L-N, e.g., a level of energy stored at the start of the time period P. The stochastic model 16 may thereby effectively model probabilistic variability 22 in the level of energy 14L stored by the power system 10 for different possible energy storage charge and discharge decisions as weather 20 probabilistically varies across the time periods P in the sequence.

Where the stochastic model 16 is a Markov chain model, for instance, the Markov chain model may include one or more states for each of the time periods P, where different states for a time period P-n represent different combinations of weather 20 and energy storage level 14L for that time period P-n. In some embodiments, a transition between states for different time periods P is associated with a probability of the transition's occurrence. A state transition may also be associated with an operational charge or discharge action, e.g., that is modeled as occurring as part of transitioning between the states so as to constitute the net amount (or percentage) by which energy storage in the electric power system 10 is charged or discharged over the associated time period. In this case, where a state's stored energy level 14L is the level of energy stored at the start of that state's time period P-n, a transition from that state defines an operational charge or discharge action that is to be performed with respect to the state's stored energy level 14L; the state transition's charge or discharge action thereby governs how a state's stored energy level 14L is to change in the stochastic model 16 so as to dictate the next state's stored energy level 14L. Indeed, the next state's stored energy level 14L may be equal to the previous state's stored energy level 14L as adapted according to the state transition's charge or discharge action.

In any event, in some embodiments, the equipment 30 obtains candidate stochastic models associated with different candidate sets of value(s) 24V for the design or operational parameter(s) 24. For each of the candidate stochastic models, the equipment 30 calculates a level of energy 14L stored by the power system 10 at each time period P-n that results in a minimum expected impact of renewable energy production variation occurring over the time horizon 18 due to the probabilistic variability 22 modeled by that candidate stochastic model. The equipment 30 then determines the value(s) 24V for the design or operational parameter(s) 24 to be the value(s) 24V in the candidate set that is associated with the candidate stochastic model that yields the smallest minimum expected impact.

Generally, then, as compared to existing approaches, some embodiments herein utilize completely different theoretical and computational platforms which inherently deal with uncertainty efficiently and/or which are suited to determining required storage levels for multi-day periods, incorporating uncertainty. Some embodiments apply such platforms to electric power so as to deal with the unique aspects of electric power physics—the instantaneous nature of matching supply to demand. In doing so, some embodiments make a heretofore intractable problem computationally efficient and demonstrate practical utility.

More particularly, some embodiments provide a methodology for planning Long Duration Energy Storage (LDES) with capacities greater than 12 hours and/or for dealing with the variability of renewable production over seasons and multi-day weather 20. Some embodiments do so by exploiting inventory management and reliability techniques heretofore not used in electric power. In particular, some embodiments consider energy storage as the ‘inventory’ in a production and delivery framework. This contrasts with power system energy storage that has always been addressed via analysis that schedules the optimal charging and discharging of power. Some embodiments herein instead use analyses that focus on determining the optimal level of stored energy 14, or constraints on total stored energy levels 14L, that are required to achieve resource adequacy considering renewable production uncertainty.

Some embodiments accordingly address the multi-day storage problem by tackling two fundamental challenges. Firstly, some embodiments account for the inherent stochastic nature of weather patterns, by accounting for how frequent, severe, and prolonged weather events impact renewable energy production. Secondly, some embodiments employ sophisticated analysis and optimization techniques that span multiple days, moving beyond conventional production cost simulations to effectively manage and optimize energy storage strategies over extended time horizons. This combination of addressing weather-related uncertainties and optimizing energy storage decisions over extended durations represents a complex yet critical frontier in advancing renewable energy integration and grid stability.

Some embodiments in this regard employ probabilistic weather modeling with a focus on insolation and/or wind speed to identify periods of renewable production shortfall characterized by frequency, duration, and/or intensity using statistical methods to construct a Markov Process Model (MPM) of weather events and renewable production impacts. Some embodiments use statistical information from that modeling to determine the required level of stored energy on a weekly or monthly basis to bridge expected renewable shortfalls with a target confidence level, and/or determination of operational decision rules for recharging LDES given weather forecasts. Alternatively or additionally, some embodiments use statistical information, historical net load, and/or renewable profiles to determine daily and/or intra-day required levels of stored energy for use in improved scheduling/dispatching of LDES. Alternatively or additionally, some embodiments enable determination of the LDES portfolio (energy, durations/power of different components of the LDES portfolio) required to provide that stored energy, including available recharging between shortfall periods. Some embodiments even enable validation of the LDES portfolio in an 8,760-hour simulation modified to co-optimize storage charging and discharging over the time frame of the longest LDES duration in the portfolio. Some embodiments furthermore extend to calculation of other revenues available to LDES (energy arbitrage, ancillaries) given the target energy levels, and/or enable analysis of different scenarios of PV, wind, V2G, Demand Response development.

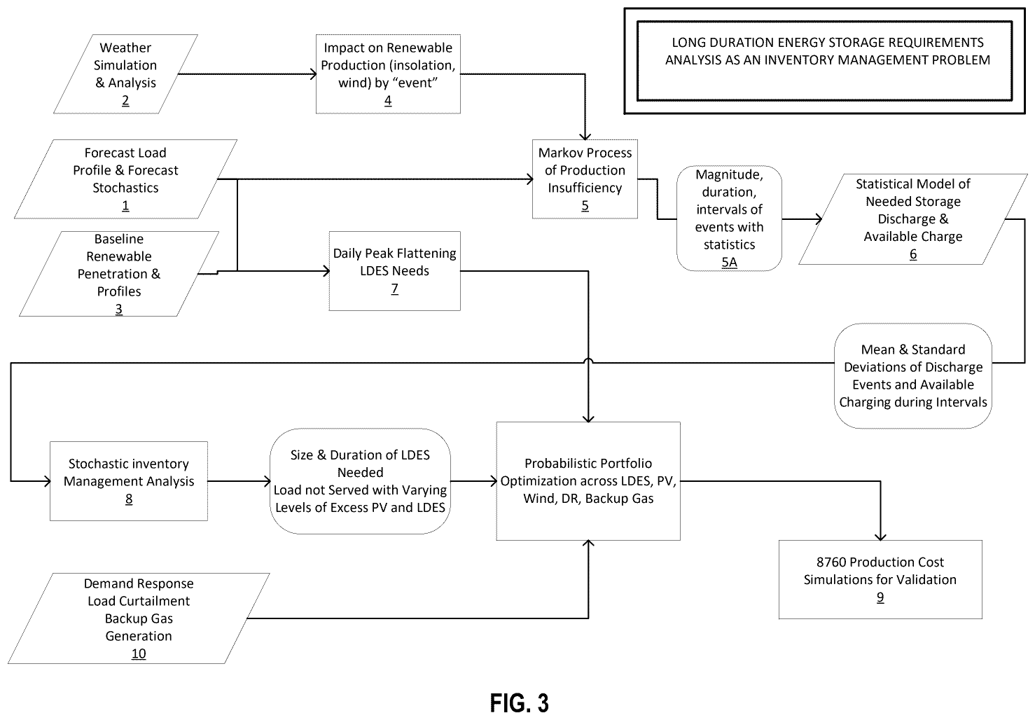

FIG. 3 shows the overall process according to some embodiments where a time period P has a duration of one day. Statistics of weather patterns and events (Block 2) may be translated into a form that can be used to develop corresponding statistics of renewable production and load, accounting for correlations and linkages between different events (Block 4). Statistics of renewable production (Block 3) and load (Block 1) may be translated into statistics of the energy gap to be filled by LDES (and other resources such as gas and DR in other scenarios) (Block 5). The total stored energy requirement is a function of not simply the worst renewable production shortfall but of the worst combination of renewable energy shortfalls including the spacing of them in time that the state decides to plan for. The stored energy needs are evaluated using a Markov process arrival model that has random arrivals of weather events of different intensities, random departures that are the end of the event, and/or which incorporates correlations via altered arrival probabilities as a function of recent arrivals (Block 5). Such a model may be created in appropriate off-the-shelf software tools and used for repeated simulations. These models may produce statistics such as (in this case) the number of times a given event occurs in a month, its duration, the standard deviation of those values are, and so on (Block 5A). The models may also provide insights into the overall behavior of the system. These statistical models result in a statistical model (block 6) of the energy insufficiency to be filled by discharging stored energy, or alternatively, excess energy available to recharge energy storage. The Inventory Management Analysis (block 8) leads to a calculation of the expected requirement for LDES capacity and duration so as to meet statistical requirements for assuring energy sufficiency. This in turn leads to a probabilistic optimal scheduling and minimization of total cost (production cost and cost of unserved load) including the use of LDES.

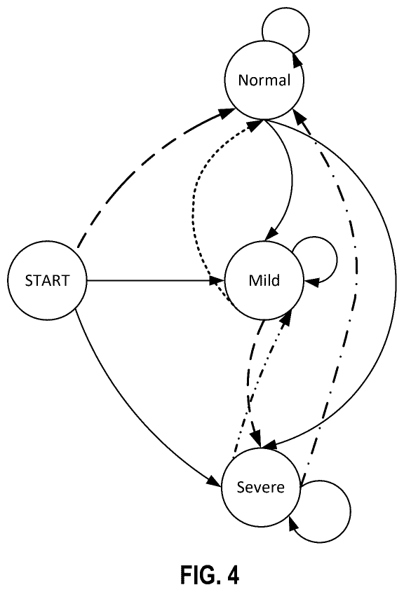

FIG. 4 shows a simple example of the stochastic model 16 in the form of an MPM used for modeling weather events. Mild and Severe weather events are defined with different probabilities of occurrence and modeled probabilities for transitions between states, e.g., which may be calibrated to historical weather event data for the region of interest. For example, the normal state may represent a sunny day, a mild state may represent a day cloudy enough to decrease PV production noticeably (e.g., by a first threshold level for at least a first threshold duration), and a severe state may represent a day with storms, dark clouds, etc. that significantly reduce PV (e.g., by a second threshold level for at least a second threshold duration).

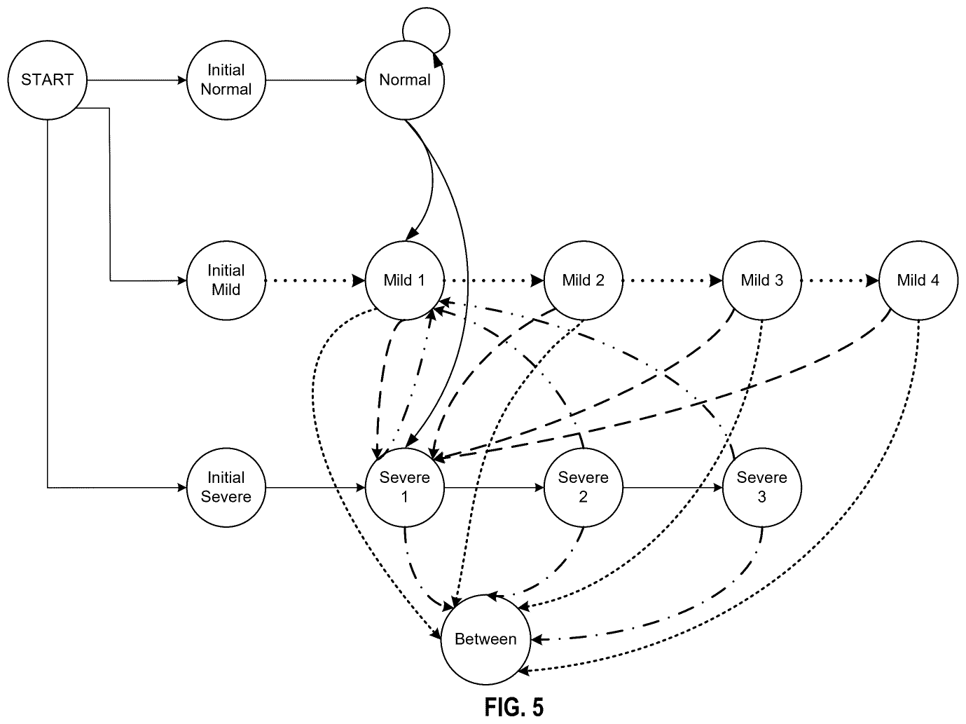

A disadvantage of this weather process model is that it is mathematically possible for a state to persist for a larger number of days than is realistic—for instance, if the Severe state has a probability of repeating of 50%, there is an approximately 3% chance that the event persists for 6 days, which is unrealistic. This is resolved by modifying the MPM to reflect successive days of persistence for weather events, with finite maximum duration. FIG. 5 shows another example of the stochastic model 16 that addresses this issue.

In this model in FIG. 5, there are a maximum number of days in a given state before it must exit and transition to a different state. This also will allow separate collection of statistics on the number of events of different durations. It allow can allow different “rewards” or “costs” attributable to 2^{nd}, 3^{rd}, etc. days in a state. In the specific example of FIG. 5, this representation limits the duration of severe events to 3 days and mild events to four. This illustration is done in “per unit”. Where 1 p.u energy unit is total load over a 24 hour period. (as in 800,000 MWH for the state). This results in a combined weather-inventory Markov model which has specific memory of the duration of weather events.

This may allow easy tracking in Markov simulations of the duration of events (which the classical model does not), as well as the time between events. Some embodiments therefore model/analyze a day as a critical time step and model the balance among load, renewable production, LDES charging and discharging (and other impacts such as DR) on a daily basis.

However, the weather statistics and behavior change significantly across the seasons, so the characteristics of the MPM may be adjusted month to month According to some embodiments, then, the problem varies month to month (or day to day), e.g., with baseline energy produced by PV on a “normal” day and/or baseline load profile on a “normal” day. Note that significant load variability will correlate closely with weather state.

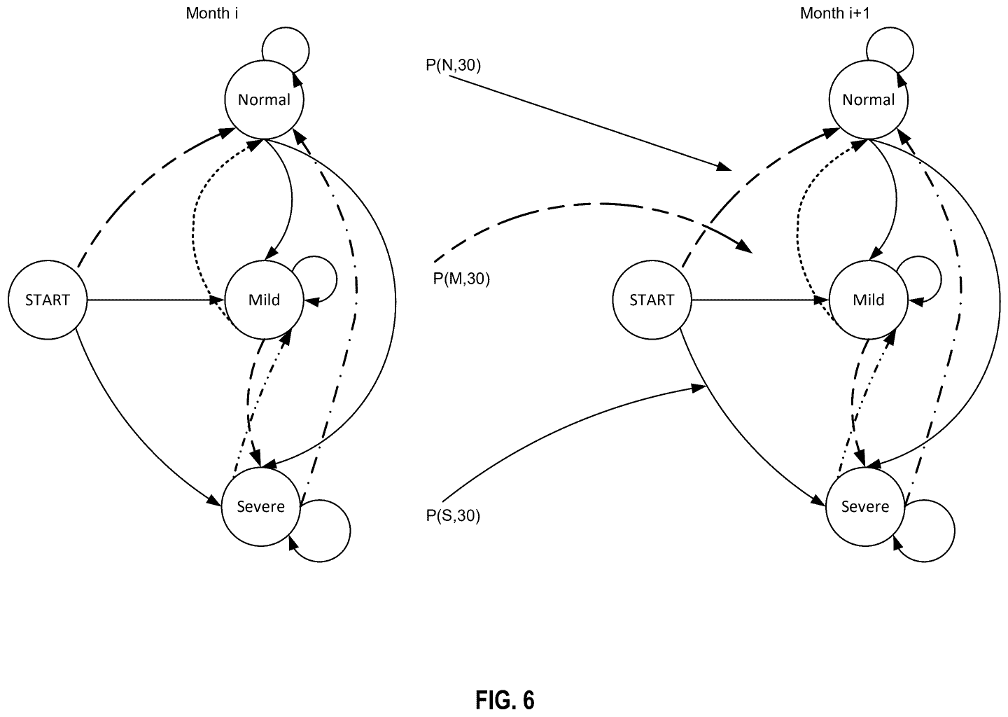

FIG. 6 shows one approach for this where the stochastic model 16 is formed from a combination of month-specific MDM models. In this example, the stochastic model 16 is formed from separate MPM models for each month that are linked by using the end state probabilities of one month as the initial state starting probabilities for the next.

Note that the steady state probabilities of being in each state directly can be calculated. And, for that matter, the probability of being in a given state at each day in the month may be calculated. Depending upon seasonal variations in a particular geography, after 1 month or 30 days the model changes in some embodiments. An alternative calculation is the probability of each state in each day explicitly given a set of initial conditions, derived from the prior month. And—the average # of days in each state is not the only important outcome. Some embodiments for example seek to know the statistics (e.g., a probability distribution function, pdf), to calculate the “rewards” and “costs” in terms of total days with insufficient generation of different amounts over the course of the month, to calculate how different storage capacities and PV capacities affect outcomes, and/or to simulate LDES operations day by day. So, as described above, a Monte Carlo simulation of the Markov chain is indicated in some embodiments, e.g., which may involve 30 steps through a nine state chain in this example, ending up with chain of states for 30 days for each simulation.

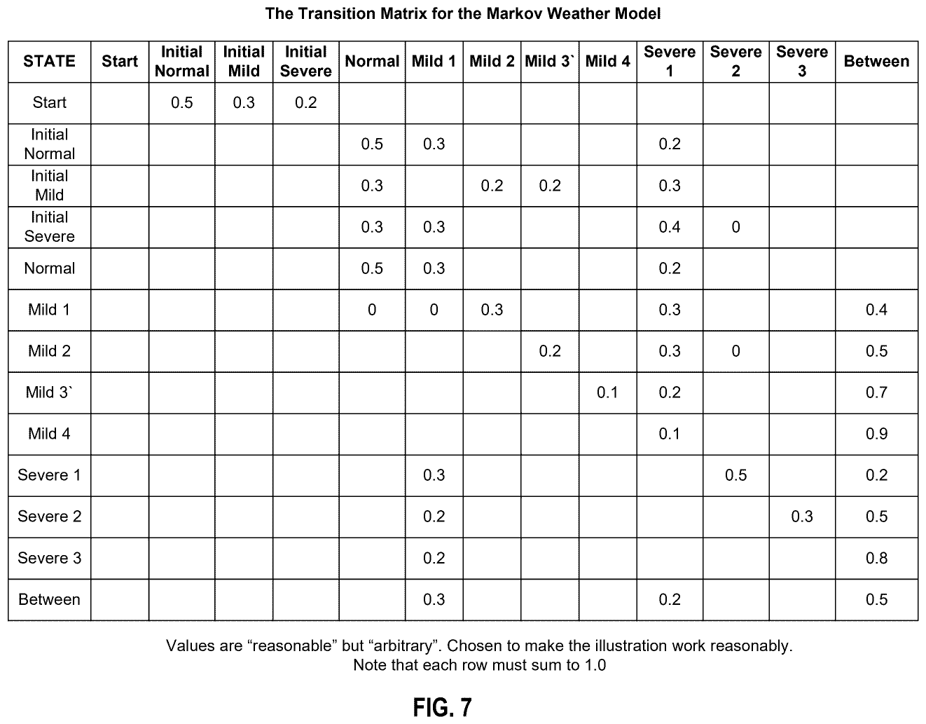

FIG. 7 shows one example transition matrix for a Markov weather model according to some embodiments.

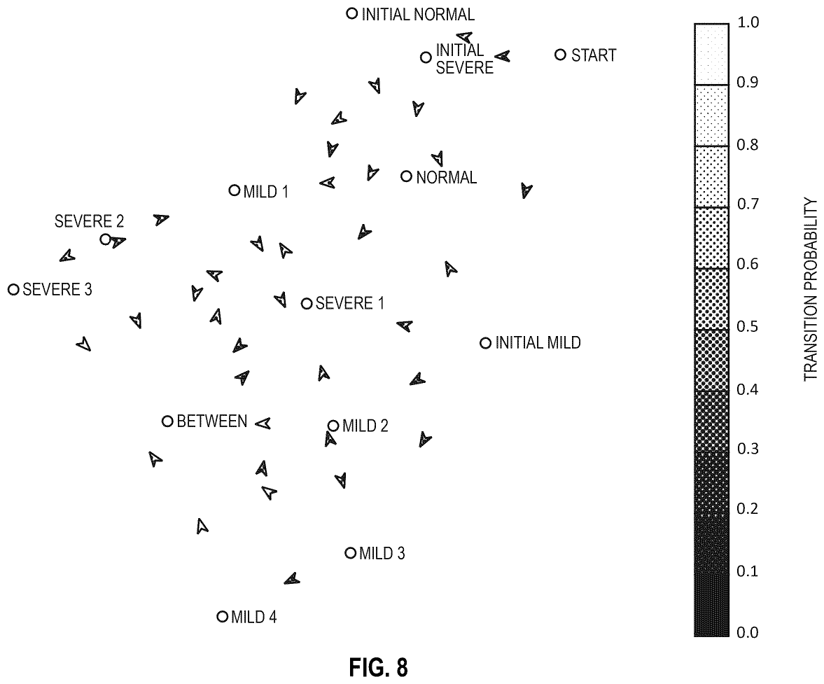

FIG. 8 shows a Markov model with state transition probabilities according to one example.

Note that one property of MPM is that simple closed form expressions for the probability of being in a given state at any step in the process may be calculated. Furthermore, the asymptotic behavior of the model—the probabilities of being in a given state after a large number of steps, may be calculated. This allows a direct calculation of the energy storage levels needed to cover “average” weather event statistics.

For LDES planning for resource adequacy, it may be desirable to allow for weather events that are “worse” than average; or said differently to address a given confidence level (such as 2 sigma) that the system has resource adequacy. A Monte Carlo simulation of the MPM allows this calculation. Another property of an MPM is that Monte Carlo simulations are simple and computationally efficient—a difference with conventional production costing simulations where such approaches are not feasible at all.

The delays or intervals between weather events, the amounts (if any) of excess resources available, and the rates at which LDES can recharge may be factored into the development of energy schedules. The excess resources originate from the normal profiles and the scenarios for resources and load. The recharge rates can be calculated to allow the LDES to make full use of available excess resources to recharge. This required recharge rate, in turn, creates the aggregate LDES duration. Completing this step results in complete base energy schedules to be used in the operational LDES modeling. Note that in these tasks, so far, only the aggregate LDES capacity has been calculated (i.e., a total for the state for each region is determined).

If a given LDES storage duration and capacity are input to a Markov model, the model will calculate the probability of the storage being fully discharged with load not served. This is normally how this approach has been used to analyze PV, storage, and other domains. Since the process allows efficient re-simulations, this approach can be used effectively for this problem. As with the comment on operational decision rules using inventory analysis, the rules for charging decisions can be implemented and tested in the Markov model. This would provide insight into operational decision making around storage usage. Stochastic Dynamic Programming can be used to develop sophisticated decision rules.

Note that the Monte Carlo process is for weather events (or other events such as wildfire that can affect renewable production). It results in a matrix whose columns are the individual simulations, and the rows contain which state the process is in at each step in each simulation. This Monte Carlo can be used to then test different portfolios of storage and renewables, and different charging strategies. The states are translated into resource adequacy parameters using PV, wind, load profiles and accounting for correlation of load to weather, weekends, and so on via calculations. The net resource deficiency or excess drives storage requirements and is used to assess the load served or not served for each portfolio as a function of storage capacity.

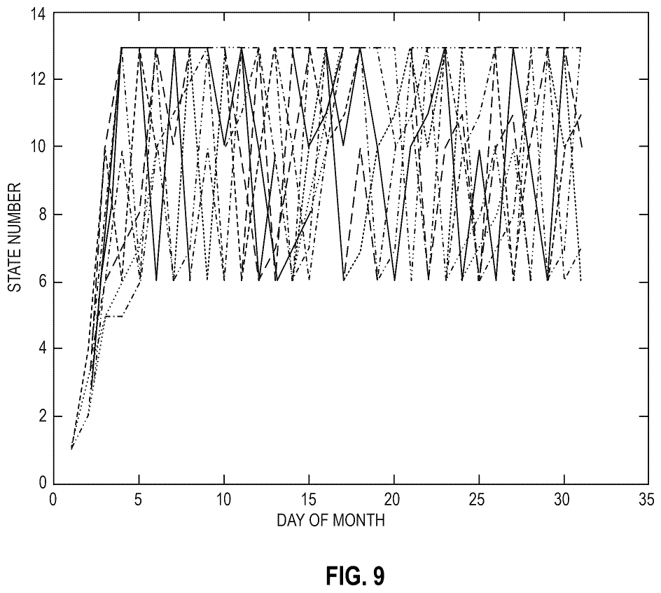

Consider now additional details of embodiments wherein the equipment 30 herein uses simulator 30S. FIGS. 9-12 show simple examples of Monte Carlo simulations, e.g., as examples of simulations from simulator 30S. Although these Figures show only 10 simulations for ease of explanation, many more simulations (e.g., thousands) may be performed in practice.

FIG. 9 shows results of simulations that each simulate transitions between states of the MPM model representing different classifications of weather across a time horizon of one month. The simulations therefore produce simulated state transition paths, with the transition between states in each path governed by the probabilistic variability in weather modeled by the MPM model.

In some embodiments, for purposes of example, different classifications of weather in different states may affect renewable energy production to different degrees. Assuming as an example that each day's load is 1 p.u., each day of “normal” weather may produce 1.1. p.u. of renewable energy (a surplus of 0.1), each day of “mild” weather may reduce renewable energy production to 0.9 p.u. (a deficiency of 0.1), and each day of “severe” weather may reduce renewable energy production to 0.6 p.u. (a deficiency of 0.4). Storage may therefore charge on ‘normal’ weather days but discharge of ‘mild’ or ‘severe’ weather days when energy is available. When storage discharge is insufficient, load is not served, i.e., some load is lost.

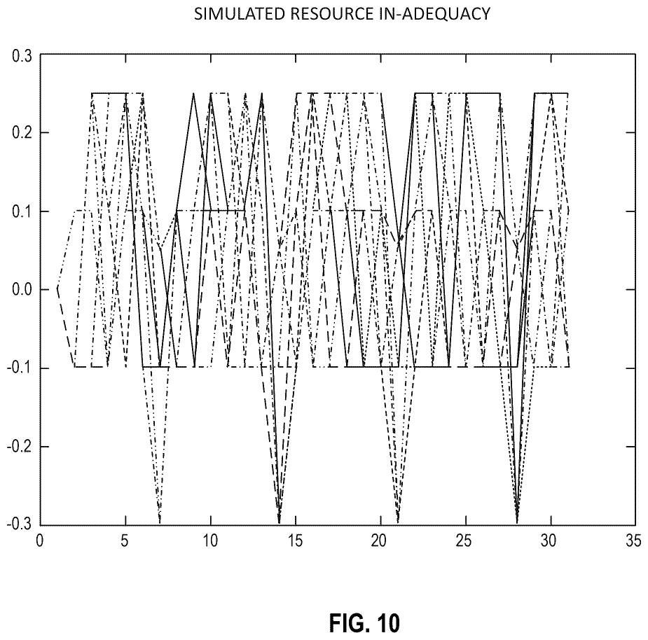

FIG. 10 shows the results of the simulations in FIG. 9 as translated into simulated daily resource shortfall based on the state things are in that day in the simulation, i.e., resource in-adequacy. Positive values are inadequacy (PV generation less than the load), whereas negative values show the excess generation (e.g., on weekends). The vector of states in each simulation is used to calculate a vector of resource deficiencies. In some embodiments not shown, this vector of deficiencies may be adjusted to reflect reduced load on weekends and/or reduced or adjusted load on holidays.

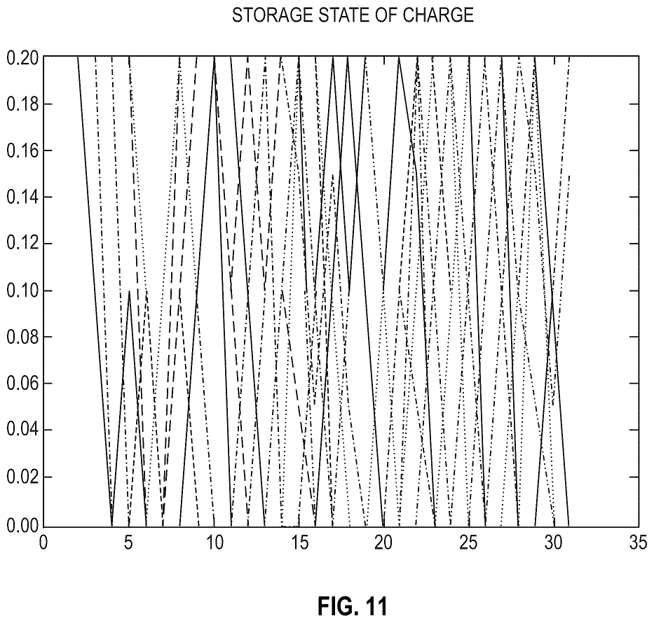

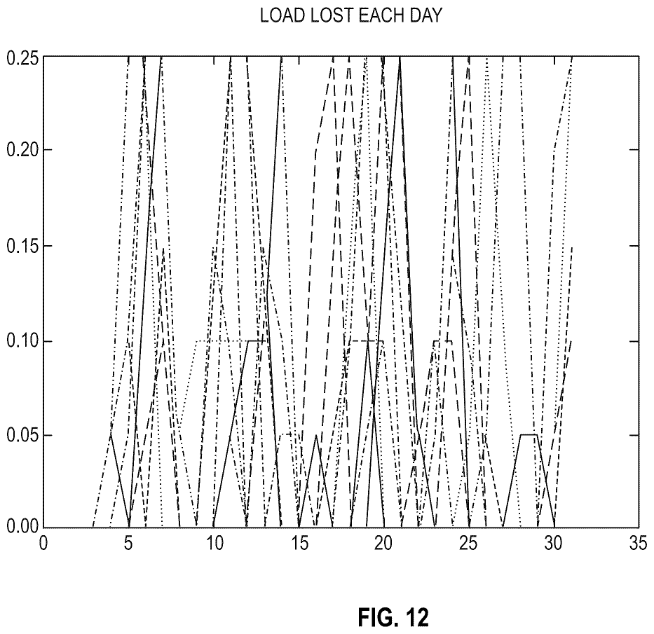

FIG. 11 shows the resulting state of charge (SoC), i.e., energy level 14L, of the energy storage 14 according to the simulations in FIG. 9, assuming a storage capacity of 0.2 p.u. Storage charges whenever there is surplus PV, until the storage 14 is fully charged to capacity. Storage discharges whenever there is a resource in-adequacy according to FIG. 10, so long as energy remains in the storage 14. Each simulation path in FIG. 11 then has a calculation of charge/discharge and a calculation of load not served. FIG. 12 shows corresponding load lost each day. As considerable load lost is lost on multiple days in this example, 0.2 p.u. storage is inadequate.

Running many simulations (e.g., 1000s) provides accurate statistics on the average for daily and total load lost, and the standard deviations of those values. Moreover, simulator 30S may perform multiple sets of Monte Carlo simulations with different storage capacities to see how load lost varies with storage capacity, e.g., in terms of mean and a statistic such as “mean+two sigma”. This is useful for setting planning criteria and determining total storage requirements.

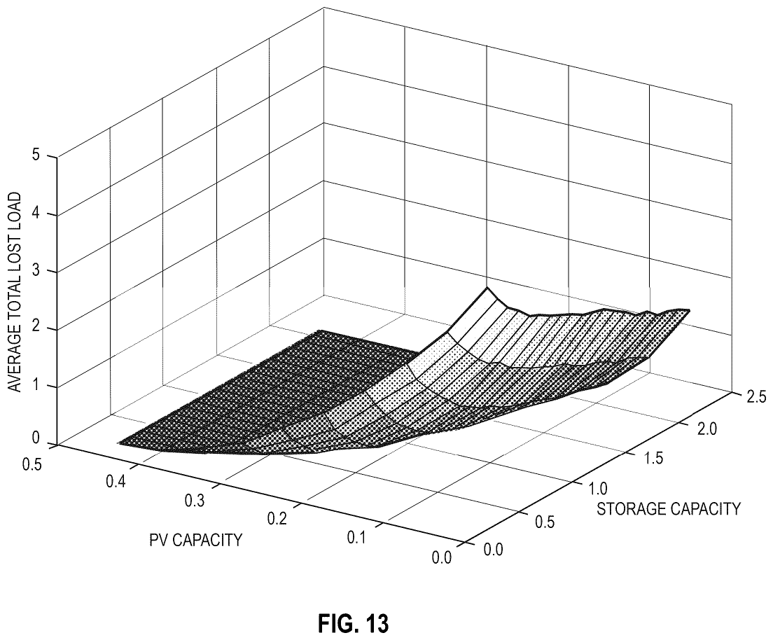

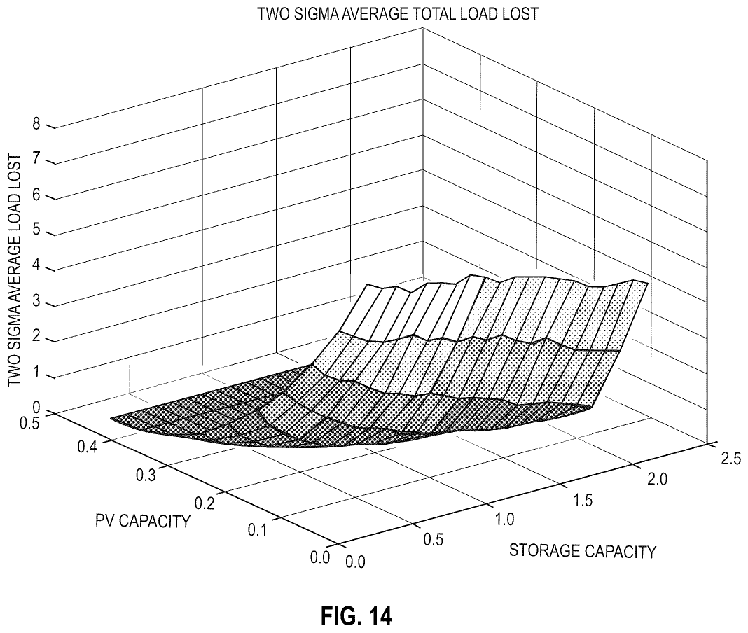

FIGS. 13 and 14 are sample results from the MPM model used in FIG. 8, showing the expected load lost statistics as averages in FIG. 13 and two sigma levels in FIG. 14, for different amounts of excess PV capacity and LDES capacity. The total lost load here is the sum of lost load across all days in a simulation; this is averaged across all simulations for each combination. This example shows a non-linear behavior.

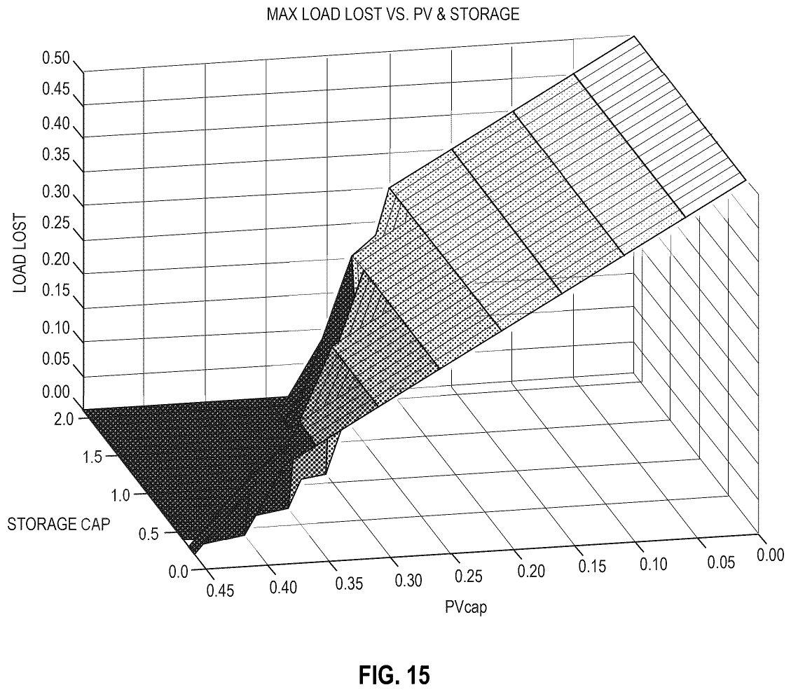

FIG. 15 shows an example determination of worst case-max load lost in a day, in per unit, as a function of the PV and storage capacities in per unit. The maximum is 0.5 p.u. which tracks the severe weather degrading PV by 50%, without any storage. Adding PV capacity reduces this as does adding storage.

From this, a daily PV profile for each weather event state can be generated. For each day in each simulation, the LDES power requirement (assuming it is fully charged) can be calculated. In this regard, the LDES power profile can be calculated as the difference between load and PV. The max of this profile will be the LDES power requirement. The LDES duration can then be calculated as LDES storage capacity/power requirement.

These results can be used with cost curves for demand response and load curtailment to make up for lost load, to identify the most cost-effective combination of LDES, excess PV, DR, and curtailment. Similarly, the cost of backup gas generation capacity can be considered. In these figures another novel concept is used to portray results—the unit of measure is the total daily energy to be delivered characterized as one per unit. The amount of storage or the amount of energy from PV is similarly expressed. This contrasts with current practice where a specific power value (typically 100 MW) is the per unit base.

It is likely that within the aggregate LDES totals (GWH and GW) determined above, it may be desirable to reduce total costs and improve flexibility by having sub-portfolios of different durations. Given the energy schedules, the power requirements between energy events, and the LDES use for market participation from the operational simulation, a selection of different LDES durations (as in the maximum required, half of that amount, etc.) will be used for a portfolio optimization allocation of LDES across durations. This portfolio optimization uses best estimates/targets for LDES costs on a technology-neutral basis.

As a simple example, one 100 MW 8-hour installation can be replaced with two 100 MW 4-hour installations, which are operated sequentially or at lower power levels so as to be equivalent to the 100 MW 8-hour energy storage. Relative costs of storage vs inverters and interconnections come into play, as do different flexibilities in the energy and ancillary markets.

The stored energy schedules are then used as operational constraints in a conventional 8,760-hour production cost simulation. The co-optimization period of the production costing is extended from the normal 24 hours (or the 100 hours being used by Form) to match the time frame of the energy scheduling.

Some embodiments furthermore may enable LDES capacity to be used in peak renewable production months to gain revenues from energy arbitrage and ancillaries participation, subject to the energy level constraints determined in the earlier steps.

This step also validates the LDES aggregate portfolio determined earlier to validate whether it is operationally feasible.

Note that some embodiments above do not attach ‘rewards’ to the states or the transitions in the stochastic model 16. Other embodiments by contrast may assign, for each state in the model, an “award” or “cost” associated. This vector of state awards, the “award vector” is constructed to reflect metrics of being in that state, e.g., in these examples, the amount of load not served or load lost from the combination of weather-driven renewable production and storage state of charge. This award vector is then used in the Markov simulations to calculate total award (total load lost) in each simulation and thus the statistics on expected, maximum, and two sigma load lost. The award vector may also be used in the direct calculation of expected load lost given state probabilities.

Some embodiments moreover may assume a simple rule for charging and discharging, e.g., do either up to maximum energy available or max state of charge, as needed or available. But in other embodiments a more sophisticated discharge strategy may be used, e.g., do not discharge under ‘mild’ weather conditions, depending upon the probability of a transition to a ‘severe’ weather event, and depending upon the cost of DR in the current state. Some embodiments use a probabilistic decision rule in the Markov process for this. Other embodiments use stochastic dynamic programming.

Consider in this regard additional details of other embodiments, e.g., where the equipment 30 herein uses dynamic programming 30D. In one or more embodiments, the Markov model award of cost vector is augmented by making it the metric of choice (production cost, lost load, etc) computed by a merit order or marginal cost economic dispatch which optimizes the allocation of production among resources of different types (gas fired, demand response, etc.) other than renewable (PV and wind). This dispatch includes curtailed (e.g. lost) load as a most expensive resource as well as energy from LDES.

This economic dispatch is extended to include multiple days in one formulation; the number of days corresponding to the current state plus the possible durations of weather events. For each probabilistic forward path in the Markov chain, a different combination of weather days is constructed and used in a multi-day dispatch, with the total energy available from LDES as a constraint. This multi day dispatch results in a marginal value of the energy available in LDES at the current state.

The probabilities of each forward path are used to weight the energy values of LDES given those paths in a total probabilistic value of LDES energy in the current state. This value is then used to dispatch the LDES along with other resources in the current state. This minimizes the expected costs of meeting energy requirements over the full range of possible weather profiles.

Alternatively, a single dispatch optimization incorporating all possible future states can be constructed and a dispatch developed which will meet the requirements of future days in all paths, given the constraint of available LDES energy. The first approach produces a current day best expected use of LDES; the second a more conservative “most reliable” use of LDES at a resulting higher total cost of production.

This alternative results in a probabilistic resource planning solution incorporating multi-day Long Duration Energy Storage.

Note that Markov models converge to a unique set of steady state probabilities for each state. By setting the initial state probabilities to the steady state probabilities, each state has the same probability of occurrence at all stages. This has two advantages-one is that it neatly solves the question of what the initial state probabilities should be. A second is that it is then possible to pre-compute the state award values (production cost) and the state to state transition costs (cost of charging/discharging LDES) once and avoid dispatch/production cost calculations at each stage. This greatly improves computational efficiency.

This yields other useful information—a probability distribution function can be computed for the distribution of the LDES state of charge throughout the time horizon. And a probability distribution function for total expected cost, expected production cost, expected lost load can be calculated.

The use of the steady state probabilities and the Discrete Stochastic Dynamic Programming allows the determination of the optimal charge/decision rule solely as a function of the state of the system. That is, given the weather day type, the number of past days in that weather type, and the current state of charge of the LDES, the charge/discharge decision and amount that will provide the lowest expected total cost is known. This makes operational use of the DSDP to determine the best charge/discharge decision straightforward operationally.

In some embodiments, another dimension of Markov states can be added to the model to represent actual available generation capacity for use in dispatch, just as PV capacity is dictated by weather states. This allows incorporation of generation reliability into the probabilistic model in a consistent manner and enables LDES planning to incorporate generation outages in a probabilistic fashion. This is an improvement of the use of simple capacity factors to de-rate different generation technologies, which fails to take into account the probabilities of multiple failures at the same time.

Furthermore, in some embodiments, the above methodologies are extended to provide probabilistic scheduling of LDES for intra-day operations. A Markov weather-storage state model and merit order dispatch is developed that uses hours instead of days as the time steps. The meaning of the random variable is “variation from forecast” and the purpose of the application is to allow the control area operator/market operator to determine how much stored energy to keep in reserve against forecast errors, at what costs.

Generally, though, some embodiments provide probabilistic analysis around drivers such as weather, load growth, and/or renewable production and incorporate multi-day co-optimization of LDES and conventional resources. Some embodiments in this regard include a framework based on principles in inventory management and probabilistic weather forecasting via Markov process and Discrete Stochastic Dynamic Programming (DSDP).

Note that operations herein deals with the resources that exist and operate them as planned; planning has to consider how the resources will be operated and how market protocols will affect their operations and financial performance. Resource planning focuses on meeting forecast peak load needs using assigned capacity factors to different resource types based on their expected availability at peak. Renewable resources get reduced capacity factors due to diurnal cycles and weather variability. Storage receives low capacity factors due to short durations. Using existing storage capacity factors for LDES ignores the longer durations and higher availability.

Resource valuations may generally be performed with 8,760 production cost simulations, which typically have successive 24-hour time horizons for optimization, which ignores the benefits of longer storage durations. Computational burdens make exploring probabilistic formulations of load, weather, and renewable response via Monte Carlo simulations difficult, if not altogether infeasible. So, “scenarios” have heretofore been used. A scenario is a particular set of inputs chosen judgmentally to represent one possible extreme set of conditions. One weakness of a scenario approach is that accounting for all worst-case permutations is very difficult if not impossible.

More particularly, known approaches to answering questions like “How much LDES should we have?” and “What characteristics (duration) should we plan for?” use existing integrated resource plans (IRPs) as baseline scenarios. As a result, they do not explore the tradeoffs between LDES and other resources, especially a battery energy storage system (BESS). Moreover, they have planning horizons that were used in the baseline IRP, so they do not explore resource portfolios that reflect 100% decarbonization goals. Additionally, known approaches use existing definitions of BESS and LDES durations such as <12 hours, <168 hours, etc., restricting analysis to these choices. Some of this is driven by state or federal definitions, and some is driven by the need to limit the number of possibilities considered.

Resource planning methodologies fall into two broad classes (i) energy merit order or profile filling dispatches traditionally used in long-term planning such as E3 RESOLVE, RESTORE, RECAP, or ASCEND PowrSIMM; and (ii) extensions of traditional 8,760-hour production cost simulations with daily optimization (via mixed integer programming) cycles to have optimization cycles as long as a week to accommodate LDES, such as Energy Exemplar PLEXOS or Form Energy FORMWARE. Both tool classes have a significant advantage in that they are based on familiar and well-used resource planning tools so that stakeholders are comfortable with them. Grid operators and state agencies commonly publish scenarios and forecasts constructed with these accepted tools and publish the models and databases for stakeholders to use in conducting their own planning. But both tool classes share a drawback in that they are based on a historical time series of load and renewable production, modified for different renewable portfolios in different scenarios. Thus, scenario development becomes critical to the results achieved, and the historical patterns limit the range of possible variability in key issues such as the adoption of PV, EV, electrification, and weather. The scenarios are thus illustrative unless many scenarios costing very large expenditures of computer time are analyzed. Another shortcoming is that studies which consider tradeoffs between LDES and other resources depend upon long-range projections of LDES costs. LDES future costs become another scenario element, ideally. A major shortcoming is that LDES economics in the future will depend upon the market rules, market products, and processes in place under scenarios of very high renewable penetration and ample LDES capacities. These are currently undefined, and studies that simply assume that existing market products and clearing processes continue in use may miss the mark.

Understandably, existing resource planning tools are based on power production as the defining variable because the dispatch of production from conventional generation has always been the result sought. Storage resources have heretofore been thought of and modeled as limited energy production resources (and loads when charging) to fit into this paradigm and existing tools such as those mentioned above. The focus in energy has heretofore been on charging and discharging (energy production) rather than storage level (energy inventory). Indeed, the regulated nature of electric power and the structure of the industry have led to storage being forced into existing asset categories, namely, generation, load, transmission, or distribution. In many cases, this forced categorization restricts the uses to which one storage resource can be put and thereby diminishes its value. It has led to valuation methodologies that are reliant on the 8,760-hour production costing paradigm.

Some embodiments herein frame storage of energy as inventory, and the focus is not so much on when the energy comes out of inventory for delivery (e.g., the equivalent of power production in the electric power problem) as much as on how much of the energy should be stored in inventory and when the energy inventory should be replenished (e.g., recharge a battery). Some embodiments thereby treat the amount of the energy in storage (i.e., the inventory level) as a parameter in monitoring, reporting, and/or decision-making.

Some embodiments use multiday LDES to buffer the system against shortfalls in daily renewable energy production caused by weather conditions or severe weather events. Some embodiments use the aggregate system energy state of charge (SoC), or level of stored energy, as a variable for analysis and/or decision-making. It addresses the one or more key shortfalls of hourly security-constrained unit commitment (SCUC): computational difficulties in optimizations over multiple days and weeks and/or incorporating probabilistic analysis.

Some embodiments frame the problem in terms of the expected daily total demand energy, expected daily renewable production given the weather state, and the cost of balancing the two via conventional generation, demand response, or load curtailment as the objective metric. Some embodiments exploit an integrated Markov chain model that uses multiday weather and renewable production states and storage states of charge as the descriptors of the Markov states. Other system states, such as generation or transmission outages, can similarly be represented (as is common in reliability analysis).

Some embodiments use the prior month's expected end-state probabilities as initial conditions in the following month to link successive Markov chain models for different months with different weather states and transition probabilities.

Some embodiments use Monte Carlo simulations of the Markov chain with different storage portfolios, renewable resources, conventional resources, and alternative decision rules for using LDES to evaluate different portfolios and operating paradigms. These simulations may be used to validate a closed-form solution. With enough draws in the Monte Carlo, the two methodologies get the same results. For a simple example with only PV and LDES as resources, on the order of 3000 draws were required to obtain results that agreed within 1%. This illustrates the difficulties in relying on Monte Carlo simulations for more complex problems.

Other embodiments exploit a mathematically complete formulation in near-closed form, e.g., eliminating the need for extensive Monte Carlo simulations. Some embodiments here use a Discrete Stochastic Dynamic Programming (DSDP) approach for developing and evaluating optimal schedules.

Some embodiments use the state probabilities and steady-state probabilities of the Markov process to directly calculate expected outcomes.

Some embodiments use reward vectors for states and transitions incorporating merit order dispatch and/or unit commitment as well as different LDES decision strategies for varied resource portfolios to evaluate expected outcomes. The hourly production cost calculated with Mixed Integer Programming (MIP) as in SCUC may be used to calculate the award vector. A value of lost load can be incorporated into the production costing formulation to ensure meaningful results when there are insufficient resources to obtain resource adequacy. The difference in production cost coming from charging or discharging decisions may be the transition cost. The award cost and transition cost can be used to evaluate each path through the DSDP and compute the expected total cost. The expected value of storage energy at each stage/state may be approximated by the difference in award costs of adjacent storage levels in the model.

Some embodiments use DSDP to assess the expected value of stored energy in each state on each day, considering the probabilities of different forward paths and state rewards. The expected value of the stored energy can then be used as a means of incorporating charging and discharging in the merit dispatch at each state and time stage. Some embodiments calculate constraints on system stored energy to be transferred to conventional SCUC for use in scheduling and dispatch.

As used herein, the term Markov process refers to a physical system that can be modeled mathematically via a Markov chain Model.

Some embodiments combine the weather and inventory process models. The Markov process has an inherent advantage over straightforward DSDP in that the stage states are inherently recombinant, so the curse of dimensionality” is avoided.

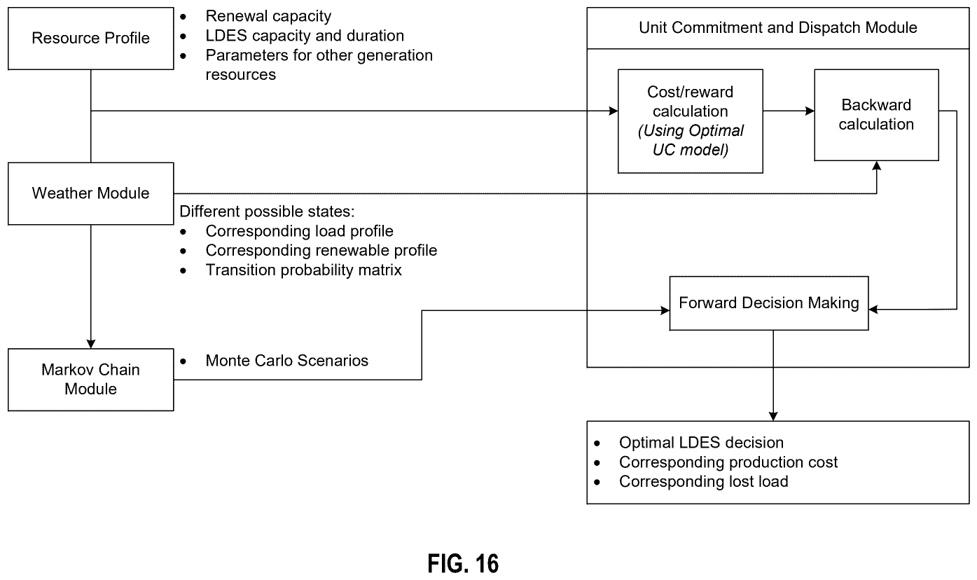

FIG. 16 shows an LDES assessment framework according to some embodiments, where modules on the left serve as inputs to the unit commitment and dispatch module on the right. The latter is formulated as DSDP, as an example of dynamic programming 30D in FIG. 1. Uncertainties in renewable production, which is the function of weather variables (e.g., solar irradiance), are formulated as a Markov chain model (MCM), as an example of stochastic model 16 in FIG. 1. A unique attribute of the proposed methodology is the integration of the Markov chain model with DSDP.

By integrating LDES SoC and renewable production (e.g., daily solar capacity factor) in one Markov chain model, a few benefits may be realized: (i) closed-form expressions for the probability of being in a state (renewable production, days in weather state, SoC) at each day or asymptotically; (ii) assuming a stationary model, the production costs and optimal dispatch only need to be computed once for each state, which has significant computational savings; (iii) the DSDP model is recombinant and does not grow exponentially with the time horizon; and (iv) DSDP yields a decision rule for LDES charge and discharge that is a function of the state.

These and other embodiments may use an MCM to model the system's state transitions (e.g., transition to sunny, rainy, or cloudy tomorrow depending on weather type today) over time. A Markov chain model is a probabilistic model of a process that assumes the weather at a given time depends only on the weather at the previous time, not on the entire history of weather. Some embodiments thereby model renewable production (e.g., photovoltaic systems) as the direct function of weather variables such as solar irradiance.

Some embodiments for example are formulated based on a 10-year, (e.g., 2011-2020) 30-min interval solar production to accomplish the following tasks: (i) Apply clustering technique to identify distinguishable weather days as in “normal, cloudy, rainy.” (ii) Calculate state transition (moving from one weather day to another one or staying in the same weather day) probabilities. In Task 1, K-means clustering is used to group daily PV capacity factors into different clusters. K-means clustering is an unsupervised machine learning algorithm used for partitioning a dataset into K distinct clusters based on the similarity of the data points. The goal of K-means is to group data points such that the points in the same cluster are as similar as possible and the points in different clusters are as different as possible. In this context, clusters are weather-type days where cloud coverage within each cluster is as similar as possible (similar expected daily solar production), and days in different weather-type day clusters are as different as possible. Silhouette coefficients may be calculated to obtain the optimal number of clusters. The Silhouette coefficient may more particularly be calculated by comparing the average distance between data points within a cluster to the average distance between data points in different clusters.

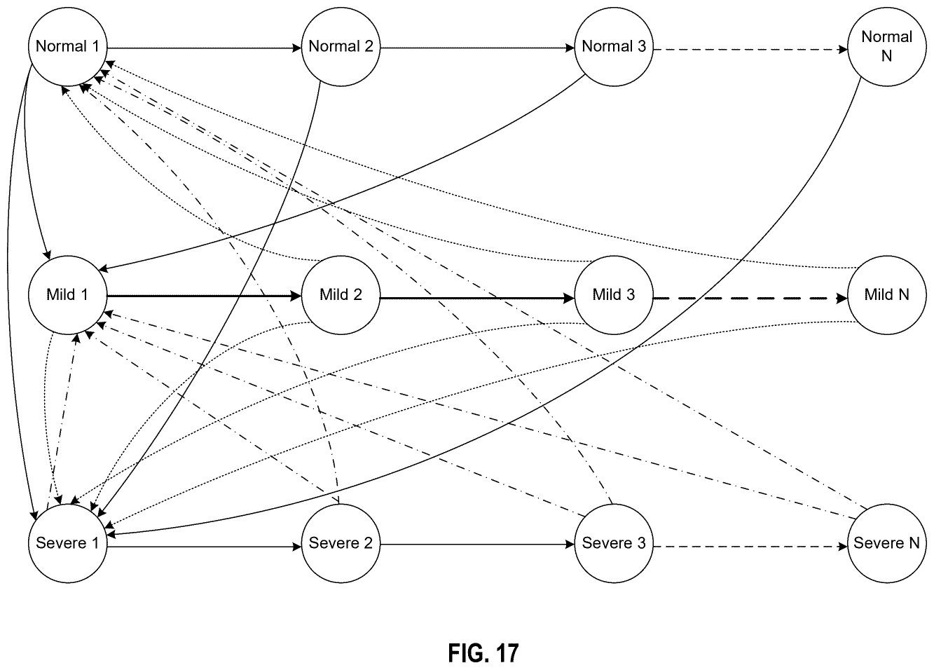

The transition schematics with three weather day classifications (normal, mild, and severe) are illustrated in FIG. 17 as an example Markov chain model according to some embodiments. In one embodiment, normal may be classified as 10% average daily PV capacity factor, mild may be classified as 21% average daily PV capacity factor, and severe may be classified as 31% average daily PV capacity favor.

Some embodiments also account for the impact of seasonality on weather clusters. Some embodiments for example are based on dividing seasons into wet and dry (e.g., December, January, February, and March), to analyze cluster formation within each period and compare it to a scenario where seasonality was not considered.

Some embodiments further augment the State Definitions and Transition Matrix to Incorporate LDES State of Charge. The state of charge (SoC) (also termed stored energy level 14L) corresponds to the inventory level in an inventory management framework. Some embodiments exploit the SoC as a Markov chain model state variable, e.g., along with the weather day. Some embodiments discretize the SoC levels to provide a finite number of states. For example, assuming 5% levels produce good granularity, some embodiments may use a 2% discretization, that is, 51 distinct levels between 0% and 100%.

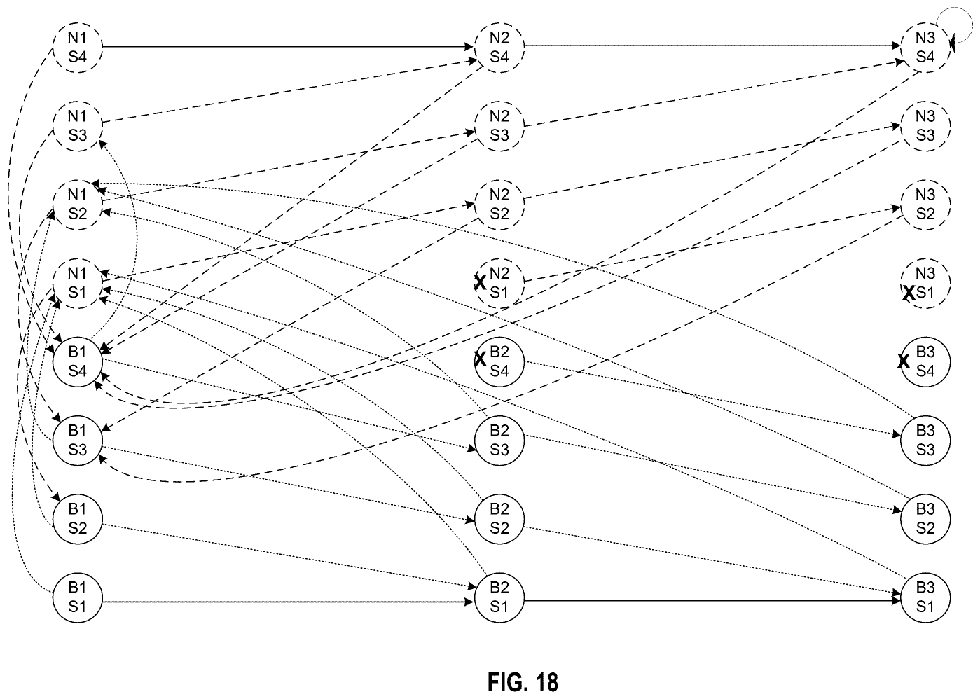

This weather and SoC model is exemplified in FIG. 18 according to one embodiment. In this case, long dashed lines indicate charging and short dashed lines indicate discharging. State S4 represents fully charged (no more possible) state of storage 14, state S3 represents an intermediate state of charge below S4 and above S3, state S2 represents another intermediate state of charge below S3 and above S1, and state S1 represents depleted (no discharge possible). X indicates the state is not allowed. Weather is either “normal or bad” (N or B) in this example. The transition probabilities are the same as in the weather-only model. The allowed transitions are a function of the SoC. All changes in weather have to go to “day 1” of normal (N1) or “day 1” of bad (B1). The second successive day of normal weather is represented as N2, whereas the third successive day of normal weather is represented as N3. Similarly, the second successive day of bad weather is represented as B2, whereas the third successive day of bad weather is represented as B3.

This state diagram and transition matrix can be generated directly from the weather model with the additional input of how many discrete levels of SoC are desired.

Additional state augmentations can be added to model increments in peak load, weekend vs. weekday behavior (load is less on weekends), conventional resource availability (outages), geographic regions with regional weather (correlated), and resource, load, and transport capacities. Examples herein are restricted to weather clusters, days in clusters, and storage SoC, but this need not be the case.

Note that DSDP formulations normally suffer from the curse of dimensionality. As the time horizon and number of stages grows, the number of possible states grows exponentially. In this formulation, the number of possible states at any stage is fixed, and the states are recombinant. Thus, the total number of states grows linearly with the number of time stages or stages.

Because the state definitions and attributes are fixed, the number of states for which award and transition costs must be performed is equal to the number of states in one stage. The same award values and transition costs will apply to the same state in all stages. This means that the production cost analysis must be performed once and only once for each day type and then for each possible LDES charge/discharge action in that day type-independent of the LDES SoC. (Some transitions are invalid.) One assumption underlying this stage in some embodiments is that the LDES can charge or discharge each day but not both. The daily net discharge/charge is the value of interest. Intraday time arbitrage of energy is the province of shorter duration storage, not LDES. If this assumption is not honored and the LDES is allowed to charge and discharge both on the same day, then the impact of each possible charge/discharge action must be evaluated for every SoC, which adds to the curse of dimensionality and burdens computation. Some embodiments examine the impact of this restriction on LDES operations, as detailed more fully later on.

For example, if there are three weather day types (normal, mild, and severe) and 200 SoC increments, 3 production costs need to be analyzed (one for each day type) and then 200 transitions for each day type for a total of 600. The number of possible paths through a 30-day DSDP considering the above is 600³⁰—a very, very large number. No reasonable number of Monte Carlo simulations and production cost solutions can approach the analysis of this problem.

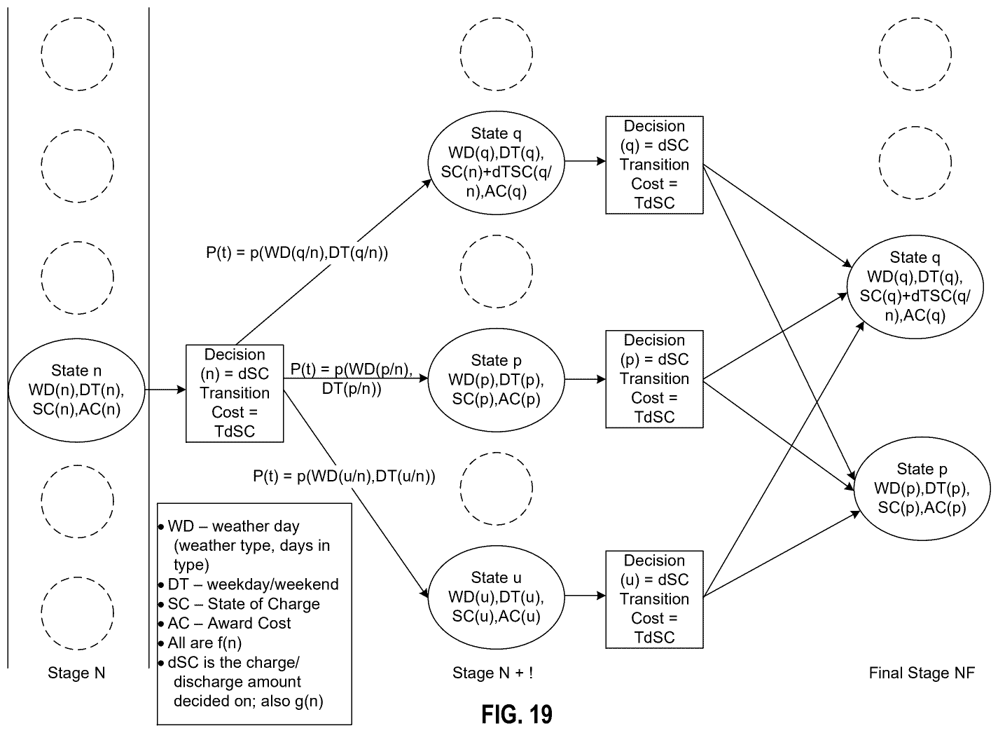

In some embodiments, multiday unit commitment and dispatch is modeled via DSDP, which is an adaptation of traditional dynamic programming designed to address problems in some embodiments with discrete states and decisions. In this context, discrete states are weather days and SoC levels. Generally, dynamic programming (DP) is a technique for solving complex problems by dividing them into simpler subproblems. DSDP is used in solving Markov decision processes (MDPs), where the system's state transitions are governed by probabilities and the objective is to find the optimal policy. Transition probabilities may be calculated. The optimal policy may involve determining the aggregated amount of LDES charge and discharge in MWh for each specific state, defined by the combination of the weather day and the initial SoC level at the beginning of the day. The end-of-day SoC depends on this optimal charge and discharge decision and determines the state for the following day. For each possible state and action, optimal hourly charge and discharge were calculated to minimize the corresponding costs (Total cost=Production+Value of Lost Load). The backward calculation process to identify the set of optimal actions is provided below, where the cost of any given day is equal to the current day cost plus the expected future cost. Expected future costs were calculated given transition probabilities. This is illustrated in FIG. 19.

The following provides the mathematical formulation of the award and transition costs:

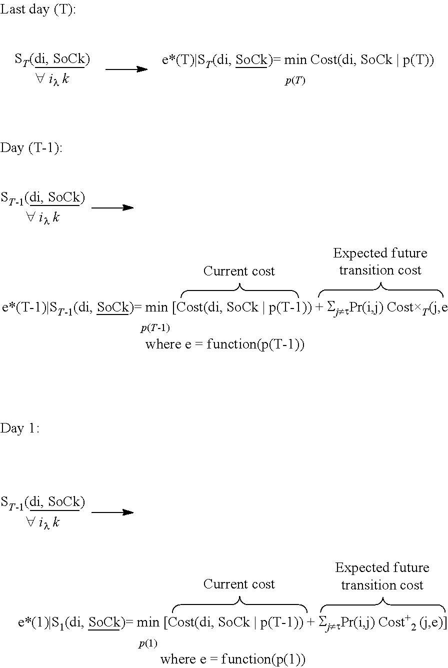

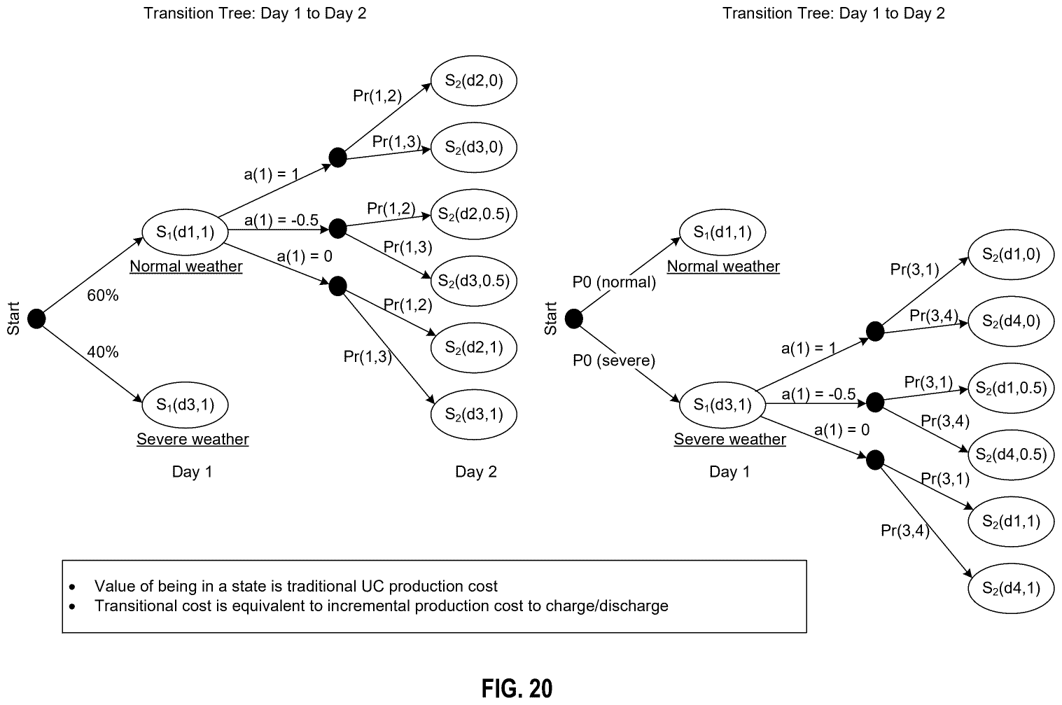

This is illustrated in FIG. 20. There are several attributes of this formulation that are key to computational efficiency and analytical results. Given the transition matrix A in the Markov Chain model in FIG. 20, the steady state probabilities of each state are given by IL where

$$\begin{matrix}P = PA \\ Pe = 1 \\ {P}_{ij} > 0\end{matrix}$$

where Π Is a vector of state probabilities, and e is a row vector of 1's. These are called the Markov state asymptotic properties. There are one or more uses of this property. Initial state probabilities can be set to the steady state probabilities. These can be for the current planning horizon (as in a month, season, or cluster) or the prior one's final state probabilities and steady-state probabilities. This permits 1) dividing the year into distinct clusters of planning horizons consistent with the cluster analysis and 2) analyzing LDES needs separately but in a coordinated way such that total results are accomplished. Also, for each state (weather day type, SoC, and other state attributes as desired), the DSDP will calculate an expected set of production costs, transition costs, and total costs. These can be weighted by state probabilities and summed to give overall expected costs, as well as other metrics such as lost load.

In some embodiments, the DSDP produces an optimal charge and discharge action at the current day and stage given the weather day type, the number of days in that weather type, and the SoC. This is the optimal action on any day given the weather day (weather type and number of days in that type) and the LDES SoC. As such, it is the optimal decision rule because of the DSDP optimization.

In a planning context, the optimal action is used to evaluate the charge and discharge transition cost that is in turn used to calculate the expected total cost (including base production cost, increment for charge and discharge, and any cost of lost load), which can then be used in a benefit-cost analysis of LDES in comparison to other generation portfolio alternatives.

Traders and operators value the stored commodity against some characterization (forecast, probabilistic model, or real options modeling) of future prices (i.e., estimating what it can be sold for). Some embodiments determine a valuation that is based on the impact the stored energy can have on the total system cost. Such a valuation would be very useful to a system operator such as an independent system operator (ISO) that is developing an operational strategy for charging and discharging the energy in an LDES.

In these embodiments, the value of stored energy (VSE) is a function of the current weather, a probabilistic characterization of future weather, the system production cost as a function of that weather, and the amount of energy in storage. For each initial day type and SoC, the DSDP can compute the expected future award and transition costs (production cost and incremental costs for charging and discharging). If this is summed over day types weighted by probabilities, then a curve of total forward cost as a function of SoC is produced. The VSE is the negative of the first derivative of this curve. One simple use of the VSE would be to help decide whether to discharge and by how much. If the VSE is lower than the current marginal production cost, it would make sense for system economics to discharge until the VSE equaled the marginal production cost. In other words, the VSE curve could be used in a conventional economic dispatch or unit commitment.

In some embodiments, extensions to the Markov chain model framework include adding layers of state variables and states to reflect weekday-weekend behavior and to have a multi-month or multi-season complete framework for a year. Indeed, weekends typically have a significantly lower load than weekdays. Historically, larger pumped storage facilities were operated on a weekly basis and targeted total depletion by the end of the day on Friday and then replenishment over the weekend. LDES recreates this potential operation. It makes a difference to the probabilistic scheduling of multiday LDES if a weather event starts on a Monday or on a Thursday; the probability of the event requiring all the energy stored in the LDES is greater in the first case than the second. Thus, a layer of Markov states or sub-states representing the seven days of the week may be exploited. These states are like the sequence of days in a weather state, but the only allowed transition is to the next day of the week with a probability of 1. Each complete state description including all substrates would then include the type of weather day, the # of days in that weather state, the LDES SoC, and/or the day of the week.

Furthermore, as described above, the steady state probabilities of the Markov chain model may be used as the initial state probabilities. In effect, the steady state probabilities are then in effect for each day in the month. But if the prior month has different weather behavior, then the steady state and final probabilities of the prior month should be the initial state probabilities of the following month. This can be done as the weather behavior dictates, seasonally, monthly, or a combination.

One property of the Markov chain model is that the passage times or the number of stages required to reach the steady state probabilities can be calculated. In some embodiments, the weather processes may have relatively short passage times in the context of a 30-stage model. However, this is going to be a property of the geography and weather. The implementation of the use of the prior month's steady state probabilities may allow for longer passage times and explicit calculations of state probabilities by stage.

Some embodiments re-use some elements of capacity planning today which assigns an average capacity factor to different resource types and technologies. For example, nuclear has a 90% capacity factor, PV has a 20% capacity factor, etc. This is used for computing reserves, for instance. The Markov formulation in some embodiments represents resource availability as a state with transition probabilities representing failure and restoration. A layer of Markov states representing conventional resource availability—actual capacity available—can be added. This will incorporate resource availability on a probabilistic basis for this analysis. This will allow exploration of LDES for reliability and resilience, at some cost in compute time. Some embodiments use a fully disaggregated SCUC in the resource planning process at some increase in compute time.

Other embodiments re-use some elements of inventory management which considers transportation as part of the problem, including, for example, routing and delays. Some embodiments incorporate transmission congestion via a transportation model in the Markov process. This may help for modeling regional weather behavior within a large geography where imports and exports are significant parts of the problem.

Still further embodiments illustrate multiday unit commitment for operational and spot market scheduling, including weather and load forecast errors. Some embodiments however provide coordination of planning and operations. Some embodiments enable operating rules for LDES, such as, “If rain is forecast within 4 days, establish minimum SoC of %.” Some embodiments implement such operating rules as constraints in SCUC. These rules can be developed as part of resource planning. Some embodiments enable determination of the minimum SoC in terms of limiting the probability of loss of load, for instance. Some embodiments incorporate the weather forecast and forecast error into the resource planning DSDP. One approach assumes zero prior information on weather, but another approach alters the transition probabilities to reflect the actual weather forecast.

In some embodiments, a Markov chain model and DSDP are provided on an hourly basis for multiday operations scheduling. This could be useful in establishing improved forecasts of balancing requirements, ramping requirements, etc.

As part of LDES operating rules, some embodiments allow LDES to operate intra-day as normal storage when the weather state and forecast are benign.

Some embodiments exploit the Markov DSDP formulation to calculate a daily and hourly VSE, which can be used in SCUC as an incremental cost curve for charging and discharging LDES.

Note that one assumption herein may be that the LDES may charge or discharge on any given day but not both. Intraday storage operations are the province of short duration storage. This assumption facilitates computational efficiency.

Other embodiments herein however may relax this assumption, but with a number of implications.

First, depending upon the size of the increment in the SoC used for discretization, the increase in computational time can be quite large, as much as a 100 times increase when the increment is 1% or less, as in the cases reported herein.

Second, for the portfolios used in the cases herein, there is insufficient generation in the morning hours before PV production has ramped up and in the evening hours after it has ramped down. Even with very high levels of PV penetration, this is the case. There is not enough short-duration (4 hours) storage in the portfolio to shift excess PV production from mid-day to the evening hours, and without multiday optimization, the short-duration storage would not be guaranteed to have sufficient charge stored for the early morning period. The cases with significant LDES in the portfolio would cover these hours if intra-day operations are permitted; otherwise, some loss of load still occurs.

There are several possible mechanisms to address this shortcoming: (1) Increase the amount of shorter duration (<12 hours) storage in the portfolio so that on normal days, there is no load lost. In this approach, the tool is used to assess the combined portfolio of short- and long-duration storage. (2) Accept the computational cost for relaxing the intraday restriction on LDES operations. This is the best choice in terms of the answers reached, at some cost in compute time. The compute time would still be reasonable for examining one case of LDES and PV configurations. (3) Modify the algorithm and code to relax that restriction when necessary to avoid lost load. This approach, in conjunction with increasing short-duration storage, might be a good solution in terms of accuracy, results, and compute time. (4) Increase the size of the discretization stage in the SoC, reducing the compute burden.

Generally, though, some embodiments herein treat energy in storage as inventory, rather than as another kind of generator (as traditional). Instead of making the decision-variable how much to charge or discharge and computing the state of charge from that, some embodiments instead make the state of charge as the decision variable and compute when to charge or discharge from that. That is, in some embodiments, the states in the model/system are defined at least in part by the state of charge (SoC).

Some embodiments may thereby contrast with approaches that optimize generation (or generation+storage) by optimizing one time series of PV production and load, and then optimizing over the course of a time frame (e.g., day, month) to minimize production cost against that time series. Such a conventional approach is deterministic (given weather, what's the optimal path?) and produces the best outcome for a particular case. By contrast, some embodiments herein seek the best outcome on average using a stochastic approach (e.g., dynamic programming). Some embodiments in this regard optimize expected outcomes, finding the answer that gives the best outcome on average across the whole space of possibilities. Some embodiments for example generally find the best state transition path through states of a probability or stochastic model to optimize an objective function, e.g., where the objective function may be to minimize a cost metric. Such a cost metric may for instance be a function of a production cost, an amount of load not served (e.g., a curtailment cost), an emissions cost, etc.

Some embodiments herein may exploit any type of probability or stochastic model, e.g., Markov model or approximation of a continuous stochastic model.

Some embodiments herein find particular applicability for electric power and/or renewable energy generation, e.g., especially renewable energy generation that is dependent on the weather. However, while renewable energy sources like solar, wind, and hydro are the most directly dependent on weather conditions, other types of energy-including non-renewables—are also influenced by the weather to some extent. Solar and wind energy rely entirely on sunlight and wind patterns, while hydropower depends on rainfall, snowmelt, and river flow. However, thermal power plants-such as those powered by coal, natural gas, or nuclear energy—also face weather-related challenges. These plants often require large amounts of water for cooling, and during heatwaves or droughts, water supplies may become too warm or scarce, forcing a reduction in output. Additionally, extreme cold can cause fuel supply disruptions, frozen equipment, and pipeline failures. Oil and gas infrastructure is particularly vulnerable to hurricanes, floods, and snowstorms, which can disrupt drilling, refining, and transportation. Weather also influences energy demand—for instance, cold spells increase heating demand (affecting natural gas usage), while heatwaves spike air conditioning loads. In short, while renewables are the most visibly tied to weather, other energy systems may be impacted by it in some way, from operational reliability to fuel availability and shifting demand. Applicable of some embodiments herein may thereby extend to non-renewable energy as well.

Some embodiments herein may determine a result that is usable to address a problem with resource planning, operations, and/or bidding. Regarding planning, some embodiments may be usable to find out how much storage should be had (e.g., to address a tradeoff between installing more PV for production or curtailing load). Regarding operations, some embodiments are usable to find out what actions an operator should take day-to-day, e.g., how much stored energy to keep in reserve at the end of the day. Regarding bidding, some embodiments are usable to maximize expected profit, e.g., to calculate the value of stored energy looking at its future value (as stored energy could be worth more than the market price of newly generated energy). Some embodiments may for instance address the situation that having a bigger storage (e.g., bigger battery) lowers the cost of producing energy in other ways (e.g., less gas burned), e.g., so as to address the trade off between a bigger battery vs. burning more gas.

Some embodiments herein may be implemented separately or in combination. For example, the multi-day weather modeling that limits the maximum duration of weather events (e.g., as in FIG. 5) may be implemented in combination with other approaches (as described) or may be implemented separately from other embodiments herein, e.g., in conjunction with traditional approaches to LDES that view stored energy as a generator rather than as inventory. As another example, exploiting a probabilistic or stochastic model may be performed as described above, but without the multi-day weather modeling (e.g., as in FIG. 5) so as to not limit weather events in terms of the maximum number of days they can persist in succession. Furthermore, some embodiments may exploit a closed-form expression rather than Monte Carlo simulations.

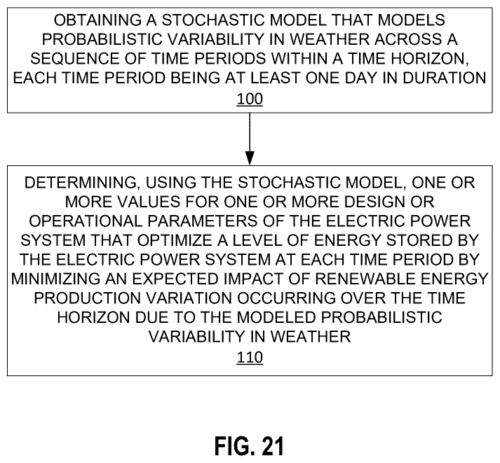

In view of the modifications and variations herein, FIG. 21 depicts a method for managing storage of energy in an electric power system 10 supplied at least in part by renewable energy sources 12 in accordance with particular embodiments. The method includes obtaining a stochastic model 16 that models probabilistic variability 22 in weather 20 across a sequence of time periods P-1 . . . P-N within a time horizon 18, each time period P-n being at least one day in duration (Block 100). The method also comprises determining, using the stochastic model 16, one or more values 24V for one or more design or operational parameters 24 of the electric power system 10 that optimize a level of energy L-1 . . . . L-N stored by the electric power system 10 at each time period P-1 . . . P-N by minimizing an expected impact of renewable energy production variation occurring over the time horizon 18 due to the modeled probabilistic variability 22 in weather 20 (Block 110).

In some embodiments, the one or more design or operational parameters 24 include one or more design parameters 24. In some embodiments, the one or more design parameters 24 include an energy storage capacity of the electric power system 10. In other embodiments, the one or more design parameters 24 alternatively or additionally include a renewable energy generation capacity of the electric power system 10.

In some embodiments, the one or more design or operational parameters 24 include one or more operational parameters 24. In some embodiments, the one or more operational parameters 24 include a schedule according to which energy storage of the electric power system 10 is charged and/or discharged.

In some embodiments, determining the one or more values 24V for the one or more design or operational parameters 24 that optimize the level of energy L-1 . . . . L-N stored by the electric power system 10 at each time period P-n comprises performing simulations that respectively simulate, for different candidate sets of one or more values 24V for the one or more design or operational parameters 24, changes in the level of energy L-1 . . . . L-N stored by the electric power system 10 across the time periods P-1 . . . P-N as weather 20 probabilistically varies according to the stochastic model 16 and impacts renewable energy production; for each of the simulations, calculating an impact of any renewable energy production variation that occurs over the time horizon 18 in the simulation; and determining the candidate set that optimizes the level of energy L-1 . . . . L-N stored by the electric power system 10 at each time period P-n to be the candidate set that, according to the simulations, has the minimum calculated impact of renewable energy production variation.

In some embodiments, the stochastic model 16 models probabilistic variability 22 in weather 20 and in energy storage level across the time periods P-1 . . . P-N in the sequence. In some embodiments, the stochastic model 16 is a Markov chain model. In some embodiments, the Markov chain model includes one or more states for each of the time periods P-1 . . . P-N in the sequence. In some embodiments, different states for a time period P-n represent different combinations of weather 20 and energy storage level for that time period P-n, and a transition between states for different time periods P-1 . . . P-N is associated with a probability of occurrence and an operational charge or discharge action.

some embodiments, said obtaining comprises obtaining candidate stochastic models associated with different candidate sets of one or more values 24V for the one or more design or operational parameters 24, and said determining comprises for each of the candidate stochastic models, calculating a level of energy L-1 . . . . L-N stored by the electric power system 10 at each time period P-n that results in a minimum expected impact of renewable energy production variation occurring over the time horizon 18 due to the probabilistic variability 22 modeled by that candidate stochastic model; and determining the one or more values 24V for the one or more design or operational parameters 24 to be the one or more values 24V in the candidate set that is associated with the candidate stochastic model that yields the smallest minimum expected impact.

In some embodiments, said determining comprises finding which state transition path through states of the stochastic model 16 optimizes an objective function. In some embodiments, the objective function is optimized by minimizing a cost metric that quantifies the expected impact of renewable energy production variation occurring over the time horizon 18.

In some embodiments, each state is associated with an award cost that is a function of an expected cost of renewable energy production in that state and an expected value of load lost due in that state. In some embodiments, each transition between states is associated with a transition cost, and the cost metric for each state transition path is a function of a sum of award costs and transition costs associated with states in the state transition path, weighted by respective probabilities of transitions between the states in the state transition path.

In some embodiments, each state of the Markov chain model is defined by a combination of (i) a time period P-n within the time horizon 18, (ii) a type of weather 20 characterizing the time period, (iii) a number of consecutive time periods P-1 . . . P-N for which the type of weather 20 has persisted, and (iv) an energy storage level at a beginning of the time period P-n, and each transition between states for different time periods P-1 . . . P-N is associated with a probability of occurrence and a net amount or percentage by which energy storage in the electric power system 10 is charged or discharged over the time period P-n.

In some embodiments, the expected impact of renewable energy production variation is a function of an expected cost of renewable energy production. In other embodiments, the expected impact of renewable energy production variation is a function of alternatively or additionally an expected value of load lost due to renewable energy production variation.

In some embodiments, the stochastic model 16 limits a number of successive time periods P-1 . . . P-N for which the same weather 20 is able to persist and/or models decreasing probability for the same weather 20 to persist over multiple successive time periods P-1 . . . P-N.

In some embodiments, the time horizon 18 spans multiple successive sets of time periods P-1 . . . P-N, and the stochastic model 16 models different probabilistic variability 22 in weather 20 during the different respective sets of time periods P-1 . . . P-N. In some embodiments, the successive sets of time periods P-1 . . . P-N are successive months. In other embodiments, the successive sets of time periods P-1 . . . P-N are successive seasons of weather 20. In some embodiments, the stochastic model 16 is a multi-stage model that comprises a combination of set-specific stochastic models which are specific to respective sets of time periods P-1 . . . P-N. In some embodiments, for each set-specific stochastic model except that which is specific to a final set in the time horizon 18, end state probabilities of the set-specific stochastic model are used as initial state starting probabilities of the set-specific stochastic model that is specific to a next set of time periods P-1 . . . P-N in the time horizon 18.

In some embodiments, the expected impact of renewable energy production variation is a function of an expected impact of renewable energy production shortfall occurring over the time horizon 18 due to the modeled probabilistic variability 22 in weather 20.

In some embodiments, the stochastic model 16 models probabilistic variability 22 in weather 20 in terms of probabilistic variability 22 between different classifications of weather 20 that respectively impact renewable energy production to different extents.

In some embodiments, the one or more design or operational parameters 24 include one or more operational parameters 24, and the method further comprises executing one or more control actions for operating the electric power system 10 according to the one or more operational parameters 24.

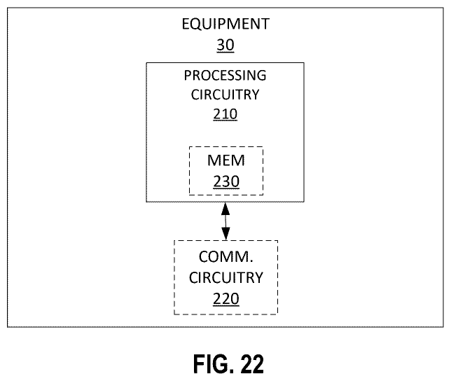

FIG. 22 illustrates equipment 30 as implemented in accordance with one or more embodiments. As shown, the equipment 30 includes processing circuitry 210. The equipment 200 may also include \communication circuitry 220, e.g., configured to transmit and/or receive information to and/or from other equipment. The processing circuitry 210 is configured to perform at least some of the processing described above, e.g., in FIG. 21, such as by executing instructions stored in memory 230. The processing circuitry 210 in this regard may implement certain functional means, units, or modules.

Note that the equipment 30 may comprise computing equipment, one or more computing devices, computing hardware, or any other equipment configuring to perform one or more aspects of the computing described herein. Note, too, that the equipment 30 may comprise a combination of hardware and software.

In this regard, some embodiments herein include a computer program comprising instructions which, when executed on at least one processor of equipment 30, cause the equipment 30 to carry out any of the respective processing described above. A computer program in this regard may comprise one or more code modules corresponding to the means or units described above.

Embodiments further include a carrier containing such a computer program. This carrier may comprise one of an electronic signal, optical signal, radio signal, or computer readable storage medium.

In this regard, embodiments herein also include a computer program product stored on a non-transitory computer readable (storage or recording) medium and comprising instructions that, when executed by a processor of equipment 30, cause the equipment YY100 to perform as described above.

Embodiments further include a computer program product comprising program code portions for performing the steps of any of the embodiments herein when the computer program product is executed by equipment 30. This computer program product may be stored on a computer readable recording medium.

In certain embodiments, some or all of the functionality described herein may be provided by processing circuitry executing instructions stored on in memory, which in certain embodiments may be a computer program product in the form of a non-transitory computer-readable storage medium. In alternative embodiments, some or all of the functionality may be provided by the processing circuitry without executing instructions stored on a separate or discrete device-readable storage medium, such as in a hard-wired manner. In any of those particular embodiments, whether executing instructions stored on a non-transitory computer-readable storage medium or not, the processing circuitry can be configured to perform the described functionality. The benefits provided by such functionality are not limited to the processing circuitry alone or to other components of equipment 30, but are enjoyed by the computing device as a whole.

Generally, then, the apparatuses described above may perform the methods herein and any other processing by implementing any functional means, modules, units, or circuitry. In one embodiment, for example, the apparatuses comprise respective circuits or circuitry configured to perform the steps shown in the method figures. The circuits or circuitry in this regard may comprise circuits dedicated to performing certain functional processing and/or one or more microprocessors in conjunction with memory. For instance, the circuitry may include one or more microprocessor or microcontrollers, as well as other digital hardware, which may include digital signal processors (DSPs), special-purpose digital logic, and the like. The processing circuitry may be configured to execute program code stored in memory, which may include one or several types of memory such as read-only memory (ROM), random-access memory, cache memory, flash memory devices, optical storage devices, etc. Program code stored in memory may include program instructions for executing one or more telecommunications and/or data communications protocols as well as instructions for carrying out one or more of the techniques described herein, in several embodiments. In embodiments that employ memory, the memory stores program code that, when executed by the one or more processors, carries out the techniques described herein.

What is claimed is:

1. A method for managing storage of energy in an electric power system (10) supplied at least in part by renewable energy sources (12), the method comprising:
obtaining a stochastic model (16) that models probabilistic variability (22) in weather (20) across a sequence of time periods (P-1 . . . P-N) within a time horizon (18), each time period (P-n) being at least one day in duration; and
determining, using the stochastic model (16), one or more values (24V) for one or more design or operational parameters (24) of the electric power system (10) that optimize a level of energy (14L) stored by the electric power system (10) at each time period (P-1 . . . P-N) by minimizing an expected impact of renewable energy production variation occurring over the time horizon (18) due to the modeled probabilistic variability (22) in weather (20).

2. The method of claim 1, wherein the one or more design or operational parameters (24) include one or more design parameters (24), wherein the one or more design parameters (24) include one or more of:
an energy storage capacity of the electric power system (10); and/or
a renewable energy generation capacity of the electric power system (10).

3. The method of claim 1, wherein the one or more design or operational parameters (24) include one or more operational parameters (24), wherein the one or more operational parameters (24) include a schedule according to which energy storage of the electric power system (10) is charged and/or discharged.

4. The method of claim 1, wherein determining the one or more values (24V) for the one or more design or operational parameters (24) that optimize the level of energy (14L) stored by the electric power system (10) at each time period (P-n) comprises:
performing simulations that respectively simulate, for different candidate sets of one or more values (24V) for the one or more design or operational parameters (24), changes in the level of energy (14L) stored by the electric power system (10) across the time periods (P-1 . . . P-N) as weather (20) probabilistically varies according to the stochastic model (16) and impacts renewable energy production;
for each of the simulations, calculating an impact of any renewable energy production variation that occurs over the time horizon (18) in the simulation; and
determining the candidate set that optimizes the level of energy (14L) stored by the electric power system (10) at each time period (P-n) to be the candidate set that, according to the simulations, has the minimum calculated impact of renewable energy production variation.

5. The method of claim 1, wherein the stochastic model (16) models probabilistic variability (22) in weather (20) and in energy storage level across the time periods (P-1 . . . P-N) in the sequence.

6. The method of claim 5, wherein the stochastic model (16) is a Markov chain model, wherein the Markov chain model includes one or more states for each of the time periods (P-1 . . . P-N) in the sequence, wherein different states for a time period (P-n) represent different combinations of weather (20) and energy storage level (14L) for that time period (P-n), and wherein a transition between states for different time periods (P-1 . . . P-N) is associated with a probability of occurrence and an operational charge or discharge action.

7. The method of claim 5, wherein said obtaining comprises obtaining candidate stochastic models associated with different candidate sets of one or more values (24V) for the one or more design or operational parameters (24), and wherein said determining comprises:
for each of the candidate stochastic models, calculating a level of energy (14L) stored by the electric power system (10) at each time period (P-n) that results in a minimum expected impact of renewable energy production variation occurring over the time horizon (18) due to the probabilistic variability (22) modeled by that candidate stochastic model; and
determining the one or more values (24V) for the one or more design or operational parameters (24) to be the one or more values (24V) in the candidate set that is associated with the candidate stochastic model that yields the smallest minimum expected impact.

8. The method of claim 5, wherein said determining comprises finding which state transition path through states of the stochastic model (16) optimizes an objective function, wherein the objective function is optimized by minimizing a cost metric that quantifies the expected impact of renewable energy production variation occurring over the time horizon (18).

9. The method of claim 8, wherein each state is associated with an award cost that is a function of an expected cost of renewable energy production in that state and an expected value of load lost due in that state, wherein each transition between states is associated with a transition cost, and wherein the cost metric for each state transition path is a function of a sum of award costs and transition costs associated with states in the state transition path, weighted by respective probabilities of transitions between the states in the state transition path.

10. The method of claim 5, wherein each state of the Markov chain model is defined by a combination of (i) a time period (P-n) within the time horizon (18), (ii) a type of weather (20) characterizing the time period (P-n), (iii) a number of consecutive time periods (P-1 . . . P-N) for which the type of weather (20) has persisted, and (iv) an energy storage level at a beginning of the time period (P-n), and wherein each transition between states for different time periods (P-1 . . . P-N) is associated with a probability of occurrence and a net amount or percentage by which energy storage in the electric power system (10) is charged or discharged over the time period (P-n).

11. The method of claim 1, wherein the expected impact of renewable energy production variation is a function of one or more of:
an expected cost of renewable energy production; and/or
an expected value of load lost due to renewable energy production variation.

12. The method of claim 1, wherein the stochastic model (16) limits a number of successive time periods (P-1 . . . P-N) for which the same weather (20) is able to persist and/or models decreasing probability for the same weather (20) to persist over multiple successive time periods (P-1 . . . P-N).

13. The method of claim 1, wherein the time horizon (18) spans multiple successive sets of time periods (P-1 . . . P-N), and wherein the stochastic model (16) models different probabilistic variability (22) in weather (20) during the different respective sets of time periods (P-1 . . . P-N).

14. The method of claim 13, wherein the successive sets of time periods (P-1 . . . P-N) are:
successive months; or
successive seasons of weather (20).

15. The method of claim 13, wherein the stochastic model (16) is a multi-stage model that comprises a combination of set-specific stochastic models which are specific to respective sets of time periods (P-1 . . . P-N), wherein, for each set-specific stochastic model except that which is specific to a final set in the time horizon (18), end state probabilities of the set-specific stochastic model are used as initial state starting probabilities of the set-specific stochastic model that is specific to a next set of time periods (P-1 . . . P-N) in the time horizon (18).

16. The method of claim 1, wherein the expected impact of renewable energy production variation is a function of an expected impact of renewable energy production shortfall occurring over the time horizon (18) due to the modeled probabilistic variability (22) in weather (20).

17. The method of claim 1, wherein the stochastic model (16) models probabilistic variability (22) in weather (20) in terms of probabilistic variability (22) between different classifications of weather (20) that respectively impact renewable energy production to different extents.

18. The method of claim 1, wherein the one or more design or operational parameters (24) include one or more operational parameters (24), and wherein the method further comprises executing one or more control actions for operating the electric power system (10) according to the one or more operational parameters (24).

19. The method of claim 1, wherein the one or more design or operational parameters (24) include one or more design parameters (24), wherein the one or more design parameters (24) include a portfolio of generation resources, demand management, and a calculated cost of load not served.

20. The method of claim 1, wherein the expected impact of renewable energy production variation is a function of an expected cost of production from non-renewable resources.

21. A non-transitory computer-readable storage medium on which is stored instructions that, when executed by processing circuitry of equipment, causes the equipment to:
obtaining a stochastic model (16) that models probabilistic variability (22) in weather (20) across a sequence of time periods (P-1 . . . P-N) within a time horizon (18), each time period (P-n) being at least one day in duration; and
determining, using the stochastic model (16), one or more values (24V) for one or more design or operational parameters (24) of an electric power system (10) that optimize a level of energy (14L) stored by the electric power system (10) at each time period (P-n) by minimizing an expected impact of renewable energy production variation occurring over the time horizon (18) due to the modeled probabilistic variability (22) in weather (20).

22. Equipment (30) for managing storage of energy in an electric power system (10) supplied at least in part by renewable energy sources (12), the equipment (30) comprising processing circuitry (210) configured to:
obtain a stochastic model (16) that models probabilistic variability (22) in weather (20) across a sequence of time periods (P-1 . . . P-N) within a time horizon (18), each time period (P-n) being at least one day in duration; and
determine, using the stochastic model (16), one or more values (24V) for one or more design or operational parameters (24) of the electric power system (10) that optimize a level of energy (14L) stored by the electric power system (10) at each time period (P-1 . . . P-N) by minimizing an expected impact of renewable energy production variation occurring over the time horizon (18) due to the modeled probabilistic variability (22) in weather (20).
